(19) United States
(12) Patent Application Publication
(10) Pub. No.: US 2008/0083967 A1
(43) Pub. Date: Apr. 10, 2008

(54) Capacitor integrated in semiconductor device

(76) Inventors: Toshifumi Nakatani, Osaka (JP); Atsushi Maruyama, Kanagawa (JP)

Correspondence Address: WENDEROTH, LIND & PONACK L.L.P., 2033 K. STREET, NW, SUITE 800, WASHINGTON, DC, 20006, US

(21) Appl. No.: 11/898,175

(22) Filed: Sep. 10, 2007

(30) Foreign Application Priority Data
Oct. 5, 2006 (JP) 2006-274386

(51) Int. Cl. H01L 29/00

(52) U.S. Cl. 257/534; 257/E29.001

(57) ABSTRACT

Provided is a capacitor integrated in a semiconductor device which allows a large capacitance per unit area; small production variations in a capacitance; a high Q-value; and a high self-resonant frequency. To attain this, each of a first wiring layer and a second wiring layer includes a wire group on an input side and a wire group on an output side. A lead-out wire included in the wire group on the input side in the first wiring layer and a lead-out wire included in the wire group on the input side in the second wiring layer are disposed so as to overlap with each other when viewed from a direction of lamination of the wiring layers. A lead-out wire included in the wire group on the output side in the first wiring layer and a lead-out wire included in the wire group on the output side in the second wiring layer are disposed so as to overlap with each other when viewed from the direction of lamination of the wiring layers. The wires which generate capacitances three-dimensionally intersect with each other when viewed from the direction of lamination of the wiring layers.

### BACKGROUND OF THE INVENTION

1. Field of the Invention

The present invention relates to a capacitor integrated in a semiconductor device, which uses metal wires integrated in a semiconductor integrated circuit. More particularly, the present invention relates to a capacitor integrated in a semiconductor device, whose capacitance is large and which requires a small number of masks when manufactured in a semiconductor process.

2. Description of the Background Art

In a semiconductor integrated circuit, a capacitor is indispensable. Among characteristics which are required of the capacitor, as the first one, a large capacitance per unit area is cited. This is because when the capacitance per unit area is large, a chip size can be decreased, thereby enabling a reduction in cost. As the second one, a high Q-value is cited. This is because when the Q-value is high, a loss is decreased, thereby improving noise characteristics of a circuit. As the third one, small variations in characteristics is cited. This is because when the variations in characteristics are small, variation margins of the circuit can be decreased, thereby allowing a low power consumption or the like.

As a kind of a capacitor integrated in a semiconductor device, there are a MOS capacitor, a MIM capacitor, a fringe capacitor, and the like. The above-mentioned three capacitors respectively have advantageous and disadvantageous characteristics and are utilized properly in accordance with applications. Among these capacitors, the fringe capacitor has a small capacitance per unit area when compared with the other capacitors, although the fringe capacitor has a low variation characteristic and a high Q-value characteristic in an RF (Radio Frequency). Furthermore, the fringe capacitor has a merit that a number of pieces of mask to be used can be decreased, as compared with the MIN capacitor which requires an additional mask for using a thin-film dielectric layer.

FIG. 21 is a diagram illustrating a configuration of a capacitor 110 integrated in a semiconductor device, as one example of a conventional one-layer fringe capacitor, disclosed in the specification of Japanese Patent No. 3209253. A plane view is shown in (1) of FIG. 21 and a sectional view is shown in (2) of FIG. 21. In the capacitor 110 integrated in a semiconductor device, between a metal wire 4-1 on an input side and a metal wire 4-2 on an output side, a capacitance is generated in a horizontal direction in FIG. 21. In the capacitor 110 integrated in a semiconductor device, a capacitance per unit area is increased by having a configuration with comb-like shapes combined.

FIG. 22 is a diagram illustrating a configuration of a capacitor 115 integrated in a semiconductor device, as one example of a conventional multi-layer fringe capacitor, disclosed in Japanese translation of PCT international application No. 2003-530699. The capacitor 115 integrated in a semiconductor device has a configuration in which capacitors, each of which is the capacitor 110 integrated in a semiconductor device shown in FIG. 21, are disposed in a vertical direction and upper and lower metal wires thereof are respectively connected through vias. Since owing to the above-mentioned configuration of the capacitor 115 integrated in a semiconductor device, electric field coupling between the vias in a horizontal direction is added in addition to electric field coupling between the metal wires in a horizontal direction, a capacitance per unit area is increased.

FIG. 23 is a diagram illustrating a configuration of a capacitor 120 integrated in a semiconductor device, as one example of a conventional multi-layer fringe capacitor, disclosed in Japanese Laid-Open Patent Publication No. 7-283076. In the capacitor 120 integrated in a semiconductor device, a metal wire 4-4 is disposed in an upper layer above a metal wire 4-1 in a lower layer and a metal wire 4-3 is disposed in an upper layer above a metal wire 4-2 in a lower layer. Owing to this configuration, in the capacitor 120 integrated in a semiconductor device, electric field coupling between the metal wire in the upper layer and the metal wire in the lower layer is added in addition to electric field coupling between the adjacent metal wires in a horizontal direction. As a result, in the capacitor 120 integrated in a semiconductor device, a capacitance per unit area is increased.

FIG. 24 is a diagram illustrating a configuration of a capacitor 125 integrated in a semiconductor device, as one example of a conventional multi-layer fringe capacitor, disclosed in Japanese Laid-Open Patent Publication No. 11-168182. As shown in FIG. 24, the capacitor 125 integrated in a semiconductor device has a configuration in which metal wires A1, B1, A2, and B2 in a lower layer are disposed in parallel with one another; thereabove, metal wires A3, B3, A4, and B4 are disposed in parallel with one another in a direction perpendicular to the metal wires A1, B1, A2, and B2; and further thereabove, metal wires A5, B5, A6, and B6 are disposed in parallel with one another and in a direction perpendicular to the metal wires A3, B3, A4, and B4. Here, FIG. 25 is a diagram for explaining a reason why owing to the configuration of the capacitor 125 integrated in a semiconductor device, a capacitance per unit area is increased. As shown in FIG. 25, electric flux lines run obliquely from a side face of the metal wire B3 to the metal wire A1 in the lower layer and the metal wire A5 in the upper layer. In other words, capacitances are generated between the side face of the metal wire B3 and an upper face of the metal wire A1 and between the side face of the metal wire B3 and a lower face of the metal wire A5. As a result, in the capacitor 125 integrated in a semiconductor device, a capacitance per unit area is increased.

In the capacitor 110 integrated in a semiconductor device shown in FIG. 21, a capacitance per unit area is small. In the capacitor 115 integrated in a semiconductor device shown in FIG. 22, although a capacitance per unit area is large, since a capacitance between adjacent vias is utilized, variations in a capacitance, which may arise in mass-production, are large. In the capacitor 120 integrated in a semiconductor device shown in FIG. 23, although a capacitance per unit area is increased through utilizing a capacitance generated between the upper and lower layers of the metal wires, a capacitance like that which is generated by the electric flux lines running from the side face of the metal wire to the metal wires in the lower layer and the upper layer as in the capacitor 125 integrated in a semiconductor device shown in FIG. 24, is not generated (see FIG. 25). For this reason, in the capacitor 120 integrated in a semiconductor device shown in FIG. 23, a capacitance per unit area is small when compared with the capacitor 115 integrated in a semiconductor device shown in FIG. 22 and the capacitor 125 integrated in a semiconductor device shown in FIG. 24.

In the capacitor 125 integrated in a semiconductor device shown in FIG. 24, a capacitance per unit area is large, and variations in a capacitance, which may arise in mass-production, are small. FIG. 26 is a diagram illustrating the capacitor 125 integrated in a semiconductor device, when viewed from a direction of lamination of the metal wires. In FIG. 26, F, G, H, and I show four side faces of the capacitor 125 integrated in a semiconductor device. The side face F faces the side face H and the side face G faces the side face I. As shown in FIG. 26, a lead-out wire 145 included in a metal wire 140 on an input side, which has a comb-like shape, is provided along the side face F and a lead-out wire 146 included in a metal wire 141 on an output side, which has a comb-like shape, is provided along the side face H facing the side face F. In metal wires 142 and 143 which are provided in the lower layer below the metal wires 140 and 141 and have comb-like shapes, a lead-out wire 147 included in the metal wire 143 on the input side is provided along the side face G and a lead-out wire 148 included in the metal wire 142 on the output side is provided along the side face I facing the side face G. On the input side, the lead-out wire 145 in the upper layer and the lead-out wire 147 in the lower layer are connected by a lead-out wire 149 and led out to an outside of the capacitor 125 integrated in a semiconductor device. Similarly, on the output side, the lead-out wire 146 in the upper layer and the lead-out wire 148 in the lower layer are connected by a lead-out wire 150 and led out to an outside of the capacitor 125 integrated in a semiconductor device.

As described above, the capacitor 125 integrated in a semiconductor device has a configuration in which the side faces, on which the lead-out wires included in the metal wires having the comb-like shapes are provided, switch positions thereof in an alternate manner between the wiring layers. This configuration necessitates the lead-out wires 149 and 150 which have long wiring lengths. As a result, an area in a chip which the lead-out wires occupy is increased, and in addition, a parasitic resistance and a parasitic inductance of the lead-out wires are increased. For example, in a case where the capacitor 125 integrated in a semiconductor device has a quadrangular shape with one side having a length of 100 μm, since the lead-out wires 149 and 150 on the input side and the output side are required to be approximately 100 μm long, the parasitic resistance of several Ω and the parasitic inductance of approximately 0.1 to 0.9 nH accrue. As a result, the capacitor 125 integrated in a semiconductor device has a problem that due to increases in the parasitic resistance and the parasitic inductance, a Q-value is decreased and a self-resonant frequency is lowered.

In the meantime, in order to shorten the wiring lengths of the lead-out wires 149 and 150, as shown in FIG. 27, a method in which the lead-out wires 149 and 150 are respectively connected at corner portions at which the lead-out wires included in the metal wires having comb-like shapes in the respective layers are adjacent can be considered. However, since in this method, the lead-out wires 149 and 150 are required to be connected at end portions of the lead-out wires 145 to 148, parasitic resistances and parasitic inductances generated in the lead-out wires 145 to 148 are increased as compared with a case where the lead-out wires 149 and 150 are connected at middle portions of the lead-out wires 145 to 148 (see FIG. 26). As a result, as shown in FIG. 27, even if the wiring lengths of the lead-out wires 149 and 150 are shortened, the capacitor 125 integrated in a semiconductor device has a problem that due to increases in the parasitic resistance and the parasitic inductance, a Q-value is decreased and a self-resonant frequency is lowered.

### SUMMARY OF THE INVENTION

Therefore, an object of the present invention is to provide a capacitor integrated in a semiconductor device, which allows a large capacitance per unit area; small production variations in a capacitance; a high Q-value; and a high self-resonant frequency.

The present invention is directed to a capacitor integrated in a semiconductor device, which has a configuration in which N (N is an integer greater than or equal to 2) wiring layers are laminated. In order to attain the above-mentioned object, the capacitor integrated in a semiconductor device according to the present invention comprises: a metal wire in a K layer, which is provided in a Kth wiring layer (K is any of 1 through N−1); and a metal wire in a K+1 layer which is provided in a K+1th layer. The metal wire in the K layer includes: a first wire group including a plurality of first wires having predetermined shapes, which are formed by regularly combining first unit linear wires and a lead-out wire which connects the plurality of first wires having predetermined shapes to a first terminal; and a second wire group including a plurality of second wires having predetermined shapes, which are formed by regularly combining second unit linear wires and a lead-out wire which connects the plurality of second wires having predetermined shapes to a second terminal. The metal wire in the K+1 layer includes: a first wire group including a plurality of first wires having predetermined shapes, which are formed by regularly combining first unit linear wires and a lead-out wire which connects the plurality of first wires having predetermined shapes to the first terminal; and a second wire group including a plurality of second wires having predetermined shapes, which are formed by regularly combining second unit linear wires and a lead-out wire which connects the plurality of second wires having predetermined shapes to the second terminal. The plurality of first wires having predetermined shapes and the plurality of second wires having predetermined shapes are alternately arranged in each of the wiring layers so as to be evenly spaced. The lead-out wire of the first wire group in the K layer and the lead-out wire of the first wire group in the K+1 layer are connected with each other so as to overlap with each other when viewed from a direction of lamination of the wiring layers. The lead-out wire of the second wire group in the K layer and the lead-out wire of the second wire group in the K+1 layer are connected with each other so as to overlap with each other when viewed from the direction of lamination of the wiring layers. The first unit linear wires in the K layer and the second unit linear wires in the K+1 layer three-dimensionally intersect when viewed from the direction of lamination of the wiring layers, respectively. The first unit linear wires in the K+1 layer and the second unit linear wires in the K layer three-dimensionally intersect when viewed from the direction of lamination of the wiring layers, respectively.

The first wires having predetermined shapes may be zigzag-shaped wires formed by combining the first unit linear wires in a zigzag manner, and the second wires having predetermined shapes may be zigzag-shaped wires formed by combining the second unit linear wires in a zigzag manner.

The metal wire in the K layer may further include zigzag-shaped floating wires, in a periphery of regions where the zigzag-shaped wires are arranged, which are evenly spaced in a manner adjacent to the zigzag-shaped wires on both edge portions of the arranged zigzag-shaped wires, and the metal wire in the K+1 layer may further include zigzag-shaped floating wires, in a periphery of regions where the zigzag-shaped wires are arranged, which are evenly spaced in a manner adjacent to the zigzag-shaped wires on both edge portions of the arranged zigzag-shaped wires.

The capacitor integrated in a semiconductor device may further comprises: vias which respectively connect portions at which the zigzag-shaped wires in the K layer, which are connected to the first terminal, and the zigzag-shaped wires in the K+1 layer, which are connected to the first terminal, overlap with each other when viewed from the direction of lamination of the wiring layers; and vias which respectively connect portions at which the zigzag-shaped wires in the K layer, which are connected to the second terminal, and the zigzag-shaped wires in the K+1 layer, which are connected to the second terminal, overlap with each other when viewed from the direction of lamination of the wiring layers.

The capacitor integrated in a semiconductor device may further comprises: floating wires which are provided in the K+1 layer and correspond to peripheral bending portions when viewed from the direction of lamination of the wiring layers, among bending portions of the zigzag-shaped wires in the K layer, which are located in a periphery of regions where the zigzag-shaped wires are arranged; floating wires which are provided in the K layer and correspond to peripheral bending portions when viewed from the direction of lamination of the wiring layers, among bending portions of the zigzag-shaped wires in the K+1 layer, which are located in a periphery of regions where the zigzag-shaped wires are arranged; vias which connect the peripheral bending portions in the K layer and the floating wires in the K+1 layer, respectively; and vias which connect the peripheral bending portions in the K+1 layer and the floating wires in the K layer, respectively.

Shapes of the floating wires in the K+1 layer and of the floating wires in the K layer may be square, triangular, or pentagonal.

The first wires having predetermined shapes may be quadrangular wires formed by combining four pieces of the first unit linear wire in a quadrangular manner; the second wires having predetermined shapes may be cross-shaped wires formed by combining two pieces of the second unit linear wire in a cross-shaped manner; the quadrangular wires in the K layer and the quadrangular wires in the K+1 layer may be connected respectively through vias to the first terminal; and the cross-shaped wires in the K layer and the cross-shaped wires in the K+1 layer may be connected respectively through vias to the second terminal.

It is preferable that an angle at which the first unit linear wires in the K layer and the second unit linear wires in the K+1 layer intersect and at which the first unit linear wires in the K+1 layer and the second unit linear wires in the K layer intersect is each 90°.

As described above, according to the present invention, by using the wires having the zigzag shapes or the like, the lead-out wires on the input side and the lead-out wires on the output side, which are provided in the plurality of wiring layers, can be respectively disposed in the respective common positions. Owing to this, according to the present invention, a capacitor integrated in a semiconductor device which allows a large capacitance per unit area; small production variations in a capacitance; a high Q; and a high self-resonant frequency can be realized.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration example of a capacitor 10 integrated in a semiconductor device according to a first embodiment;

FIG. 2 is a diagram for describing metal wires provided in a first wiring layer which the capacitor 10 integrated in a semiconductor device comprises;

FIG. 3 is a diagram for describing wires provided in a second wiring layer which the capacitor 10 integrated in a semiconductor device comprises;

FIG. 4 is a diagram illustrating another configuration example of the capacitor 10 integrated in a semiconductor device according to the first embodiment;

FIG. 5 is a diagram illustrating another configuration example of the capacitor 10 integrated in a semiconductor device according to the first embodiment;

FIG. 6 is a diagram illustrating another configuration example of the capacitor 10 integrated in a semiconductor device according to the first embodiment;

FIG. 7 is a diagram illustrating another configuration example of the capacitor 10 integrated in a semiconductor device according to the first embodiment;

FIG. 8 is a diagram for describing a capacitance generated in the capacitor 10 integrated in a semiconductor device according to the first embodiment;

FIG. 9 is a diagram illustrating a unit cell in the capacitor 10 integrated in a semiconductor device according to the first embodiment;

FIG. 10 is a diagram for calculating a fringe capacitance C_{fringe} per unit cell in the capacitor 10 integrated in a semiconductor device according to the first embodiment in a case where an intersecting angle θ is acute;

FIG. 11 is a diagram for calculating a fringe capacitance C_{fringe} per unit cell in the capacitor 10 integrated in a semiconductor device according to the first embodiment in a case where an intersecting angle θ is obtuse;

FIG. 12 is a diagram showing a calculation result of a capacitance C₀ (θ) per unit area, which is generated in the capacitor 10 integrated in a semiconductor device in a case where an intersecting angle θ is changed from 0° to 180°;

FIG. 13 is a diagram showing a calculation result of a capacitance C₀ (θ) per unit area, which is generated in the capacitor 10 integrated in a semiconductor device in a case where W₁ and S₁ are respectively changed;

FIG. 14 is a diagram showing a calculation result of a capacitance C₀ (θ) per unit area, which is generated in the capacitor 10 integrated in a semiconductor device in a case where T and H are respectively changed;

FIG. 15 is a diagram illustrating a configuration example of a capacitor 50 integrated in a semiconductor device according to a second embodiment;

FIG. 16 is a diagram illustrating a configuration of a first modified example of the capacitor 50 integrated in a semiconductor device according to the second embodiment;

FIG. 17 is a diagram illustrating a configuration of a second modified example of the capacitor 50 integrated in a semiconductor device according to the second embodiment;

FIG. 18 is a diagram illustrating a configuration of a third modified example of the capacitor 50 integrated in a semiconductor device according to the second embodiment;

FIG. 19 is a diagram illustrating a configuration example of a capacitor 200 integrated in a semiconductor device according to a third embodiment;

FIG. 20 is a diagram illustrating metal wires 11-1, 12-1, 15-1, and 16-1 which the capacitor 200 integrated in a semiconductor device according to the third embodiment comprises;

FIG. 21 is a diagram illustrating a configuration of a capacitor 110 integrated in a semiconductor device, as one example of a conventional one-layer fringe capacitor, disclosed in the specification of Japanese Patent No. 3209253;

FIG. 22 is a diagram illustrating a configuration of a capacitor 115 integrated in a semiconductor device, as one example of a conventional multi-layer fringe capacitor, disclosed in Japanese translation of PCT international application No. 2003-530699;

FIG. 23 is a diagram illustrating a configuration of a capacitor 120 integrated in a semiconductor device, as one example of a conventional multi-layer fringe capacitor, disclosed in Japanese Laid-Open Patent Publication No. 7-283076;

FIG. 24 is a diagram illustrating a configuration of a capacitor 125 integrated in a semiconductor device, as one example of a conventional multi-layer fringe capacitor, disclosed in Japanese Laid-Open Patent Publication No. 11-168182;

FIG. 25 is a diagram for explaining a reason why owing to the configuration of the capacitor 125 integrated in a semiconductor device, a capacitance per unit area is increased;

FIG. 26 is a diagram illustrating the capacitor 125 integrated in a semiconductor device, when viewed from a direction of lamination of metal wires; and

FIG. 27 is a diagram illustrating the capacitor 125 integrated in a semiconductor device, when viewed from the direction of lamination of the metal wires.

### DESCRIPTION OF THE PREFERRED EMBODIMENTS

### First Embodiment

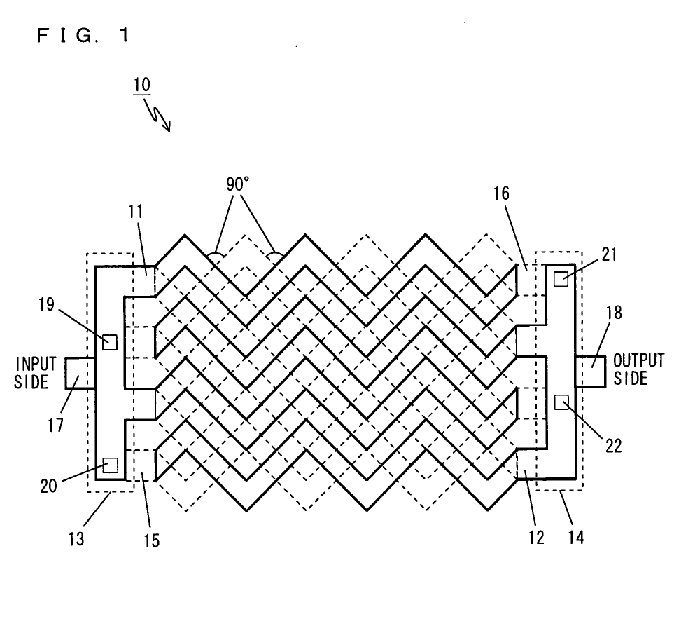

FIG. 1 is a diagram illustrating a configuration example of a capacitor 10 integrated in a semiconductor device according to a first embodiment. As shown in FIG. 1, the capacitor 10 integrated in a semiconductor device comprises a first wiring layer which is indicated by a solid line and a second wiring layer which is indicated by a dotted line. The first wiring layer comprises a metal wire 11 on a signal input side (hereinafter, simply referred to as an input side), a metal wire 12 on a signal output side (hereinafter, simply referred to as an output side), a lead-out wire 17 on the input side, and a lead-out wire 18 on the output side. The signal input side and output side may be reversed. The metal wire 11 on the input side includes a lead-out wire 13 on the input side and the metal wire 12 on the output side includes a lead-out wire 14 on the output side. The lead-out wire 17 which is connected to a terminal (not shown) on the input side of the capacitor 10 integrated in a semiconductor device is connected to the middle of the lead-out wire 13 and the lead-out wire 18 which is connected to a terminal (not shown) on the output side of the capacitor 10 integrated in a semiconductor device is connected to the middle of the lead-out wire 14. The second wiring layer comprises a metal wire 15 on the input side and a metal wire 16 on the output side. The metal wire 15 on the input side includes a lead-out wire 23 (not shown) on the input side and the metal wire 16 on the output side includes a lead-out wire 24 (not shown) on the output side. The first wiring layer and the second wiring layer overlap with each other. The metal wire 11 and the metal wire 15 on the input side are connected by vias 19 and 20 which are electrical conductors. Similarly, the metal wire 12 and the metal wire 16 on the output side are connected by vias 21 and 22 which are electrical conductors.

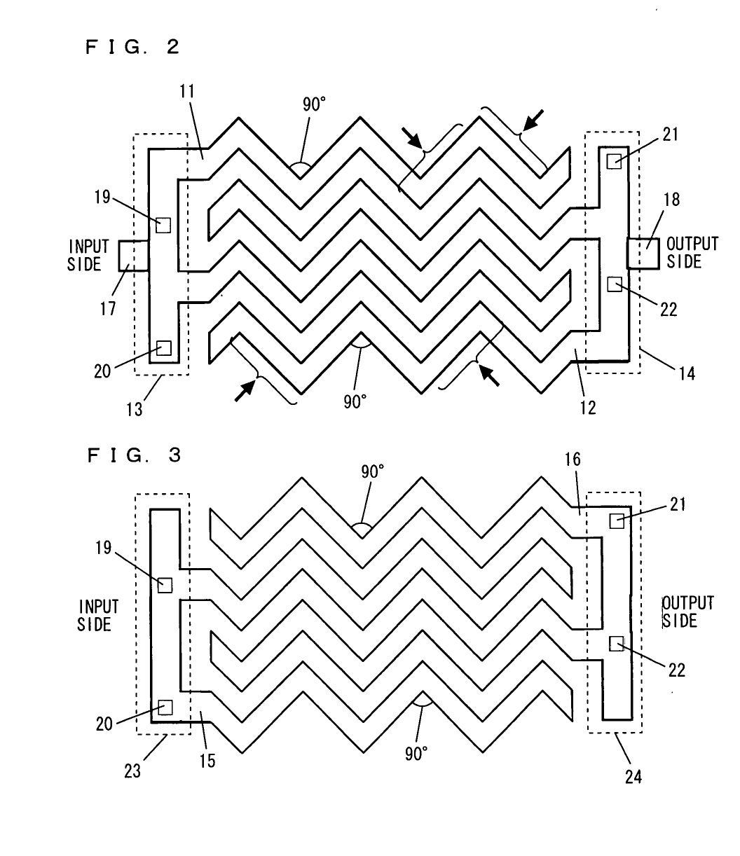

FIG. 2 is a diagram for describing the metal wires provided in the first wiring layer which the capacitor 10 integrated in a semiconductor device comprises. As shown in FIG. 2, the metal wire 11 has a configuration in which two wires (hereinafter, referred to as zigzag-shaped wires) having shapes whose straight lines bend alternately right and left (hereinafter, referred to as zigzag shapes) are connected by a lead-out wire 13. The zigzag-shaped wires also can be considered to be wires which are formed by regularly combining straight-line-shaped wires (unit straight line wires), one unit of which is each indicated by an arrow in FIG. 2. Similarly, the metal wire 12 has a configuration in which two zigzag-shaped wires are connected by the lead-out wire 14. An angle at which the zigzag-shaped wires each bend in a zigzag manner is 90°. As shown in FIG. 2, the zigzag-shaped wires of the metal wire 11 and the zigzag-shaped wires of the metal wire 12 are alternately disposed in an evenly spaced manner in the first wiring layer such that cycles in which the zigzag shapes bend in a zigzag manner are uniform.

FIG. 3 is a diagram for describing the wires provided in the second wiring layer which the capacitor 10 integrated in a semiconductor device comprises. As shown in FIG. 3, the metal wire 15 has a configuration in which two zigzag-shaped wires are connected by the lead-out wire 23 and the metal wire 16 has a configuration in which two zigzag-shaped wires are connected by the lead-out wire 24. An angle at which the zigzag-shaped wires each bend in a zigzag manner is 90°. As shown in FIG. 3, the zigzag-shaped wires of the metal wire 15 and the zigzag-shaped wires of the metal wire 16 are alternately disposed in an evenly spaced manner in the second wiring layer such that cycles in which the zigzag shapes bend in a zigzag manner are uniform.

Here, referring again to FIG. 1, a positional relationship of the zigzag-shaped wires in the first wiring layer (see FIG. 2) and the zigzag-shaped wires in the second wiring layer (see FIG. 3) in the capacitor 10 integrated in a semiconductor device will be described. As shown in FIG. 1, the zigzag-shaped wires, which are indicated by the solid line, of the metal wires 11 and 12 disposed in the first wiring layer and the zigzag-shaped wires, which are indicated by the dotted line, of the metal wires 15 and 16 disposed in the second wiring layer are disposed such that each of the cycles in which the zigzag-shaped wires of the metal wires 11 and 12 disposed in the first wiring layer bend in a zigzag manner is deviated by a half-cycle from each of the cycles in which the zigzag-shaped wires of the metal wires 15 and 16 disposed in the second wiring layer bend in a zigzag manner, when viewed from a direction of lamination of the first wiring layer and the second wiring layer.

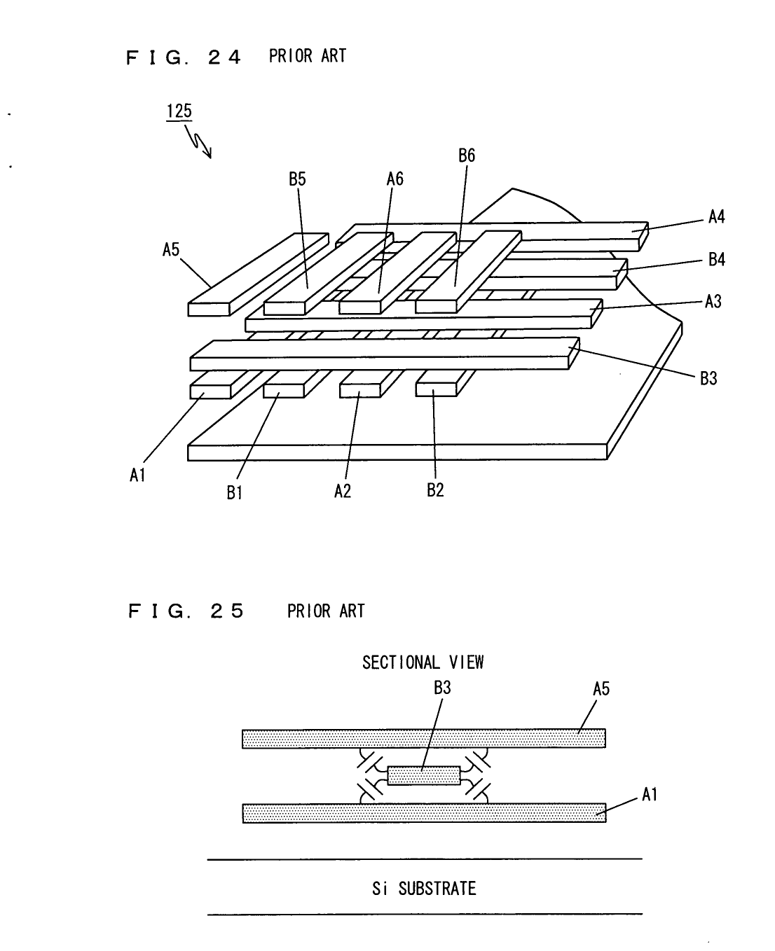

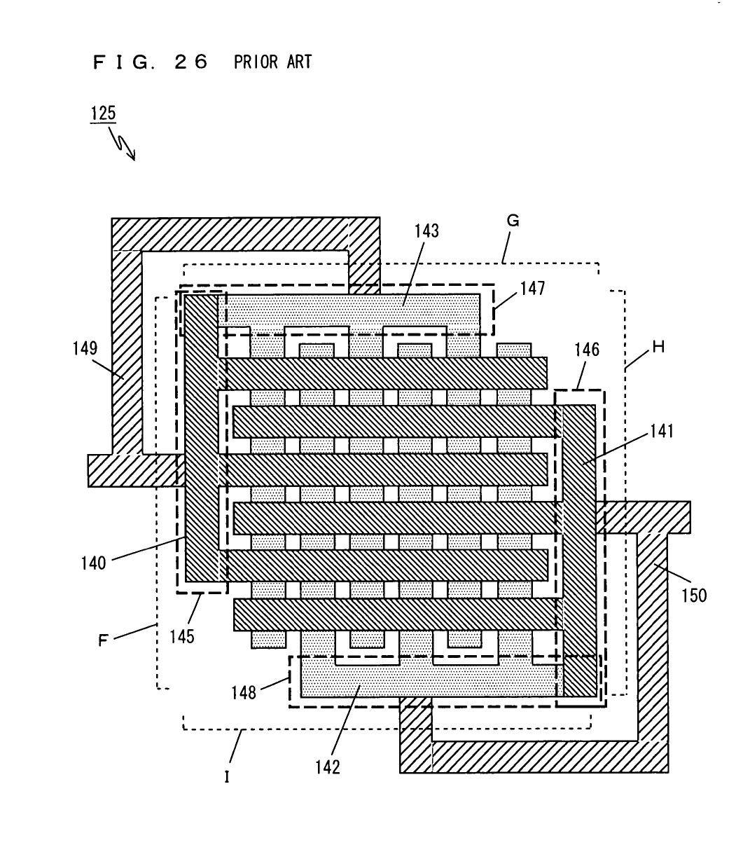

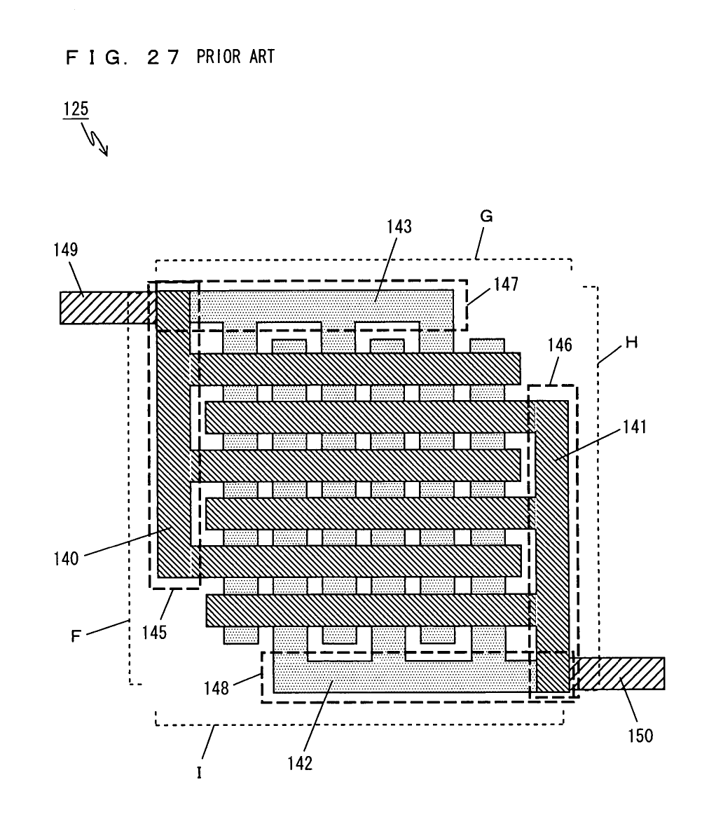

As shown in FIG. 1, in the above-described configuration, the zigzag-shaped wires, which are included in the metal wire 11 on the input side, disposed in the first wiring layer and the zigzag-shaped wires, which are included in the metal wire 16 on the output side, disposed in the second wiring layer have a plurality of portions which are orthogonal to one another when viewed from the direction of lamination of the first wiring layer and the second wiring layer. Similarly, the zigzag-shaped wires, which are included in the metal wire 12 on the output side, disposed in the first wiring layer and the zigzag-shaped wires, which are includes in the metal wire 15 on the input side, disposed in the second wiring layer have a plurality of orthogonal portions in the direction of lamination of the first wiring layer and the second wiring layer. Owing to this, the capacitor 10 integrated in a semiconductor device can attain an effect similar to that obtained by the conventional capacitor 125 (see FIGS. 24 and 26) integrated in a semiconductor device, which effect is described with reference to FIG. 25. Specifically, capacitances are generated between side faces of the zigzag-shaped wires, which are included in the metal wire 11 on the input side, disposed in the first wiring layer and upper faces of the zigzag-shaped wires, which are included in the metal wire 16 on the output side, disposed in the second wiring layer. Capacitances are generated between side faces of the zigzag-shaped wires, which are included in the metal wire 16 on the output side, disposed in the second wiring layer and lower faces of the zigzag-shaped wires, which are included in the metal wire 11 on the input side, disposed in the first wiring layer. Similarly, capacitances are generated between side faces of the zigzag-shaped wires, which are included in the metal wire 12 on the output side, disposed in the first wiring layer and upper faces of the zigzag-shaped wires, which are included in the metal wire 15 on the input side, disposed in the second wiring layer. Capacitances are generated between side faces of the zigzag-shaped wires, which are included in the metal wire 15 on the input side, disposed in the second wiring layer and lower faces of the zigzag-shaped wires, which are included in the metal wire 12 on the output side, disposed in the first wiring layer. As a result, the capacitor 10 integrated in a semiconductor device allows a capacitance per unit area to be increased as in the conventional capacitor 125 integrated in a semiconductor device.

Here, as shown in FIGS. 1 to 3, unlike in the conventional capacitor 125 integrated in a semiconductor device, in the capacitor 10 integrated in a semiconductor device, the lead-out wires 13 and 23 on the input side are provided in a common side face (position) and the lead-out wires 14 and 24 on the output side are provided in a common side face (position), when viewed from the direction of lamination of the first wiring layer and the second wiring layer. The lead-out wires 13 and 23 on the input side are connected by the vias 19 and 20, and the lead-out wires 14 and 24 on the output side are connected by the vias 21 and 22. Thus, it is only required that in the capacitor 10 integrated in a semiconductor device, the lead-out wire 17 is connected to the lead-out wire 13 on the input side and the lead-out wire 18 is connected to the lead-out part 14 on the output side. As a result, the capacitor 10 integrated in a semiconductor device allows a reduction in wiring lengths of the lead-out wires as compared with the capacitor 125 integrated in a semiconductor device shown in FIG. 26, thereby enabling suppression of parasitic resistances and parasitic inductances which are caused on the lead-out wires.

Furthermore, in the capacitor 10 integrated in a semiconductor device, the lead-out wire 17 is connected to the middle portion of the lead-out wire 13 and the lead-out wire 18 is connected to the middle portion of the lead-out wire 14. Thus, the capacitor 10 integrated in a semiconductor device allows a reduction in parasitic resistances and parasitic inductances which are caused on the lead-out wires 13, 14, 23, and 24, as compared with the capacitor 125 integrated in a semiconductor device shown in FIG. 27, in which the lead-out wire 149 is connected to the end portions of the lead-out wires 145 and 147 and the lead-out wire 150 is connected to the end portions of the lead-out wires 146 and 148.

In addition, in the capacitor 10 integrated in a semiconductor device, vias are not formed on portions (portions of the zigzag-shaped wires) which generate capacitances. Since in a case where vias are formed, the zigzag-shaped wires are required to be made thick, a capacitance per unit area is decreased. Thus, the capacitor 10 integrated in a semiconductor device realizes a capacitor integrated in a semiconductor device, whose area efficiency in generation of a capacitance is good.

As described above, in the capacitor 10 integrated in a semiconductor device, a capacitance per unit area is large and production variations in a capacitance are small, as in the capacitor 125 integrated in a semiconductor device. In addition to these, the capacitor 10 integrated in a semiconductor device allows less parasitic resistances and parasitic inductances than the conventional capacitor 125 integrated in a semiconductor device. As a result, the capacitor 10 integrated in a semiconductor device enables providing a capacitor integrated in a semiconductor device, which allows a large capacitance per unit area; small production variations in a capacitance; a high Q-value; and a high self-resonant frequency.

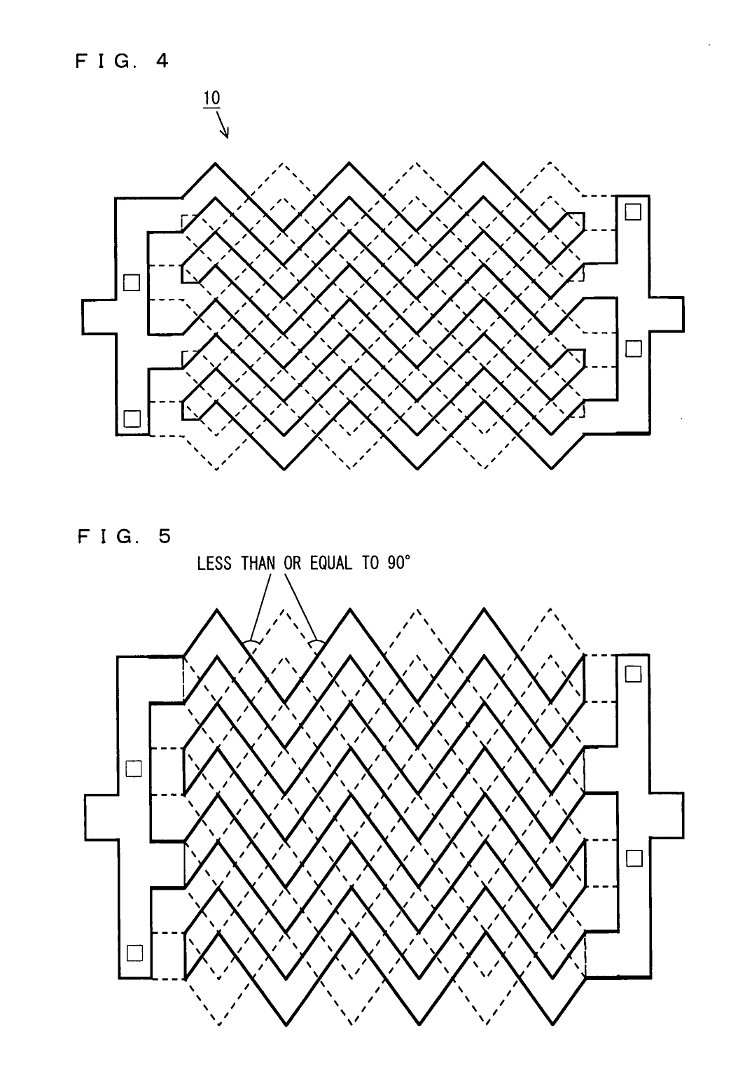

In FIG. 1, end portions of the zigzag-shaped wires in the capacitor 10 integrated in a semiconductor device are acute-angled. There may be a case where acute-angled wires constitute a violation of rules in some semiconductor processes. In such a case, for example, the acute-angled end portions of the zigzag-shaped wires in the capacitor 10 integrated in a semiconductor device may be cut in a manner shown in FIG. 4. In the above description, the configuration in which the zigzag-shaped wires in the first wiring layer and the zigzag-shaped wires in the second wiring layer three-dimensionally intersect at 90° (see FIG. 1) is shown. However, as shown in FIG. 5 or FIG. 6, a configuration in which the zigzag-shaped wires in the first wiring layer and the zigzag-shaped wires in the second wiring layer three-dimensionally intersect at an angle greater than or equal to 90° or at an angle less than or equal to 90° may be adopted. Also in the above description, the capacitor integrated in a semiconductor device, which comprises two layers of the first wiring layer and the second wiring layer is described. However, the capacitor integrated in a semiconductor device may comprise three or more wiring layers. In such a case, a capacitance per unit area can be further increased. Also in the above description, the number of the zigzag-shaped wires which are provided in each of the wiring layers is four. However, the number of the zigzag-shaped wires which are provided in each of the wiring layers is not limited to four. In the above description, when viewed from the direction of lamination of the first wiring layer and the second wiring layer, the zigzag-shaped wires included in the metal wire 11 on the input side, which is disposed in the first wiring layer, and the zigzag-shaped wires included in the metal wire 16 on the output side, which is disposed in the second wiring layer three-dimensionally intersect at a plurality of portions; and the zigzag-shaped wires included in the metal wire 12 on the output side, which is disposed in the first wiring layer, and the zigzag-shaped wires included in the metal wire 15 on the input side, which is disposed in the second wiring layer three-dimensionally intersect at a plurality of portions. However, these intersecting portions may be one or more, and further these portions may only overlap without intersecting. In such a case, a total of capacitances generated on the side faces of the zigzag-shaped wires is smaller than that generated in a case where there are the plurality of intersecting portions.

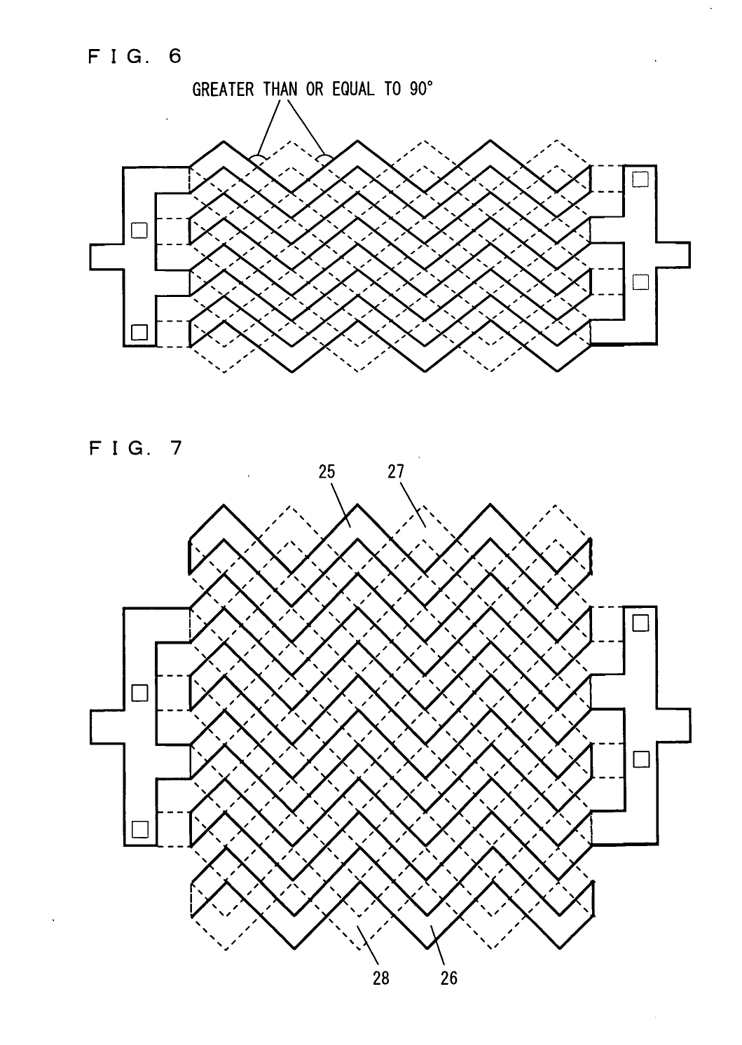

As shown in FIG. 7, floating wires 25 and 26 which have the same shapes of the zigzag-shaped wires of the metal wires 11 and 12 and are not connected to either of the metal wires 11 and 12 may be disposed in the first wiring layer at positions in a periphery of a region in which the zigzag-shaped wires of the metal wires 11 and 12 are arranged, so as to have even spaces with the zigzag-shaped wires on both edges in an adjacent manner. Similarly, floating wires 27 and 28 which have the same shapes of the zigzag-shaped wires of the metal wires 15 and 16 may be disposed in the second wiring layer. Thus, since portions of the metal wires, which generate capacitances, can be planarized, variations in a capacitance in the capacitor 10 integrated in a semiconductor device can be reduced.

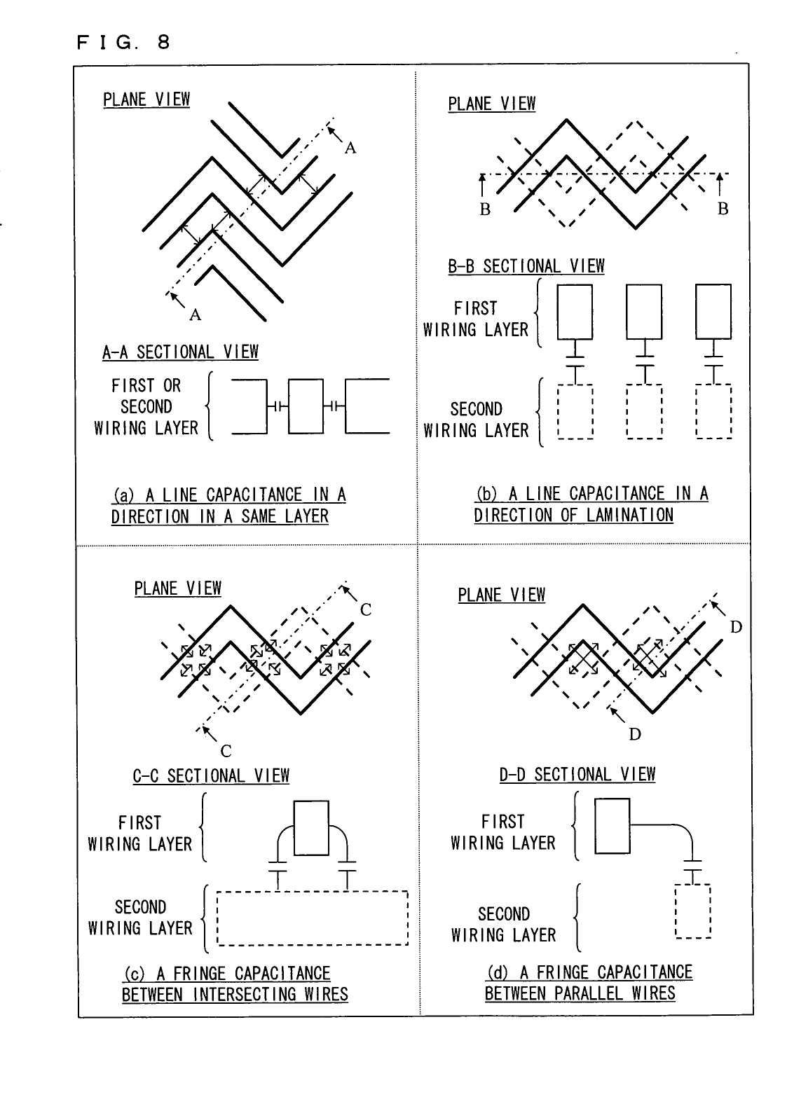

Hereinunder, a capacitance generated in the capacitor 10 integrated in a semiconductor device shown in FIG. 1 will be described. FIG. 8 is a diagram for describing the capacitance generated in the capacitor 10 integrated in a semiconductor device shown in FIG. 1. There are four kinds of the capacitance generated in the capacitor 10 integrated in a semiconductor device, which are shown in (a) to (d) in FIG. 8. Note that a plane view and a sectional view of the zigzag-shaped wires and a capacitance to be generated are shown in each of (a) to (d) in FIG. 8. The capacitance shown in (a) in FIG. 8 is a line capacitance in a direction of each of the layers, which is generated between the wires in the first wiring layer and between the wires in the second wiring layer. The capacitance shown in (b) in FIG. 8 is a line capacitance in a direction of lamination, which is generated between the wires in the first wiring layer and the wires in the second wiring layer. The capacitance shown in (c) in FIG. 8 is a fringe capacitance generated between the side faces of the wires in the first wiring layer and the upper faces of the wires in the second wiring layer and generated between the lower faces of the wires in the first wiring layer and the side faces of the wires in the second wiring layer. The capacitance shown in (d) in FIG. 8 is a fringe capacitance between parallel wires, which is generated between the side faces of the wires in the first wiring layer and the upper faces of the wires in the second wiring layer and generated between the lower faces of the wires in the first wiring layer and the side faces of the wires in the second wiring layer.

Here, in the conventional capacitor 125 integrated in a semiconductor device (see FIG. 24), although the capacitances shown in (a) to (c) in FIG. 8 are generated, the capacitance shown in (d) in FIG. 8 is not generated. In other words, in the capacitor 10 integrated in a semiconductor device according to the present invention, the capacitance shown in (d) in FIG. 8 is further generated as compared with the conventional capacitor 125 integrated in a semiconductor device.

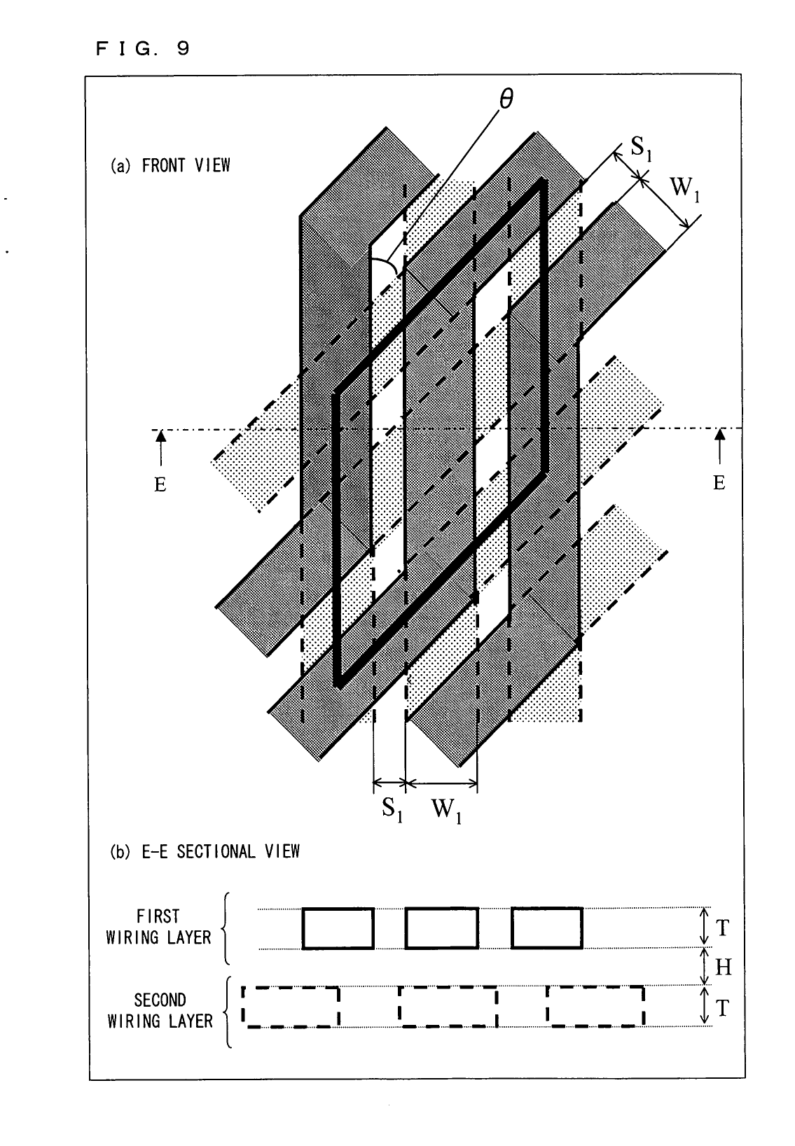

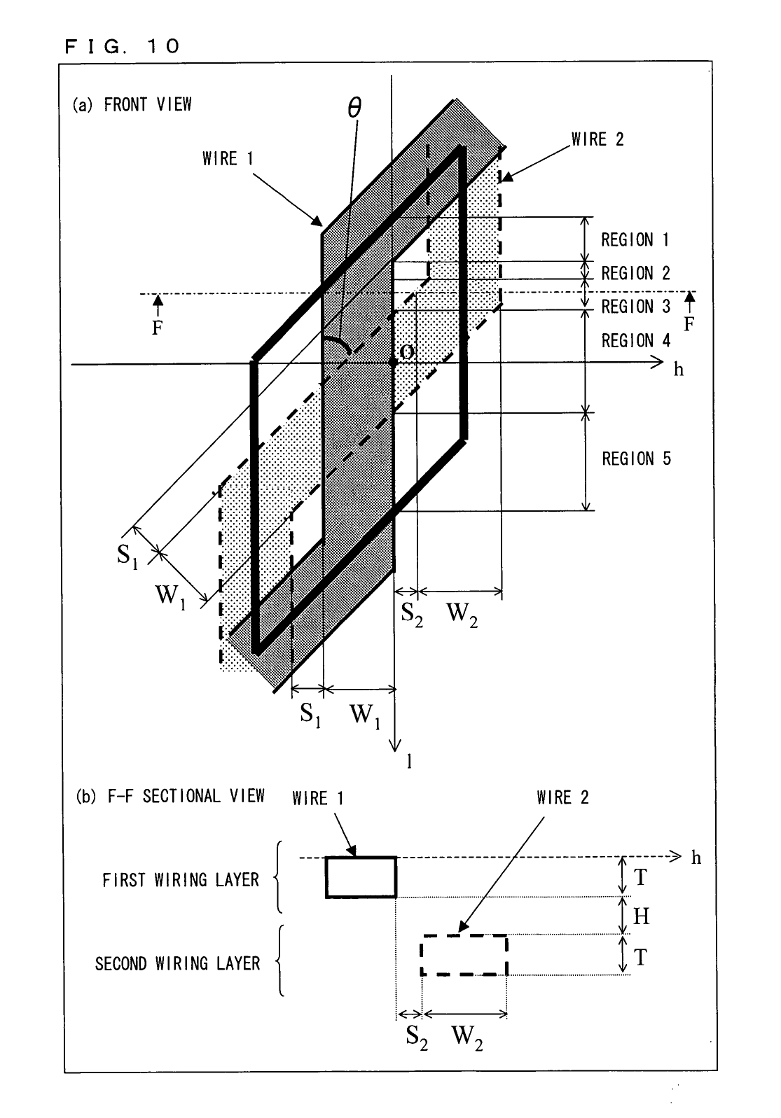

Hereinunder, an optimum value of an angle at which the wires in the first wiring layer and the wires in the second wiring layer intersect (hereinafter, simply referred to as an intersecting angle) will be considered. A calculation will be made considering a case where the wires in the first wiring layer (upper layer) and the wires in the second wiring layer (lower layer) intersect at an angle θ when viewed from the direction of lamination of the both wiring layers. FIG. 9 is a diagram illustrating a unit cell in the capacitor 10 integrated in a semiconductor device. FIG. 9(a) is a front view of the unit cell and FIG. 9(b) is a sectional view of the unit cell. A portion which is enclosed with a thick-lined quadrangle is the unit cell. The wires in the first wiring layer (upper layer) are indicated by a solid line and the wires in the second wiring layer (lower layer) are indicated by a dotted line. Here, it is supposed that a width and a thickness of the wired in the first wiring layer and the second wiring layer are W₁ and T, respectively. It is supposed that a distance between the wires in the first wiring layer and between the wires in the second wiring layer is S₁. It is supposed that a distance between the wires in the first wiring layer and the wires in the second wiring layer is H. In this case, an area of the unit cell is calculated by using a formula 1.

$$S = \frac{{( 2 {W}_{1} + 2 {S}_{1} )}^{2}}{sin θ} \qquad [ Formula 1 ]$$

With the formula 1 used, a line capacitance C_{side} per unit cell in a direction of each of the layers, shown in (a) in FIG. 8 is calculated by using a formula 2. Note that ε_{γ} is a relative permittivity and ε₀ is a permittivity of free space.

$${C}_{side} = 4 {ɛ}_{r} {ɛ}_{0} \frac{T ( 2 {W}_{1} + 2 {S}_{1} ) / sin θ}{{S}_{1}} \qquad [ Formula 2 ]$$

The line capacitance Cₚₗₐₜₑ per unit cell in the direction of lamination, shown in (b) in FIG. 8, is calculated by using a formula 3.

$${C}_{plate} = 2 {ɛ}_{r} {ɛ}_{0} \frac{{W}_{1}^{2} / sin θ}{H} \qquad [ Formula 3 ]$$

The fringe capacitance between the intersecting wires, shown in (c) in FIG. 8, and the fringe capacitance between the parallel wires, shown in (d) in FIG. 8, are calculated and added, resulting in a fringe capacitance C_{fringe} per unit cell. Intersecting angle dependence of the fringe capacitance C_{fringe} varies depending on whether the intersecting angle θ is acute or obtuse. Accordingly, hereinunder, each of the cases where the intersecting angle θ is acute and where the intersecting angle θ is obtuse will be described.

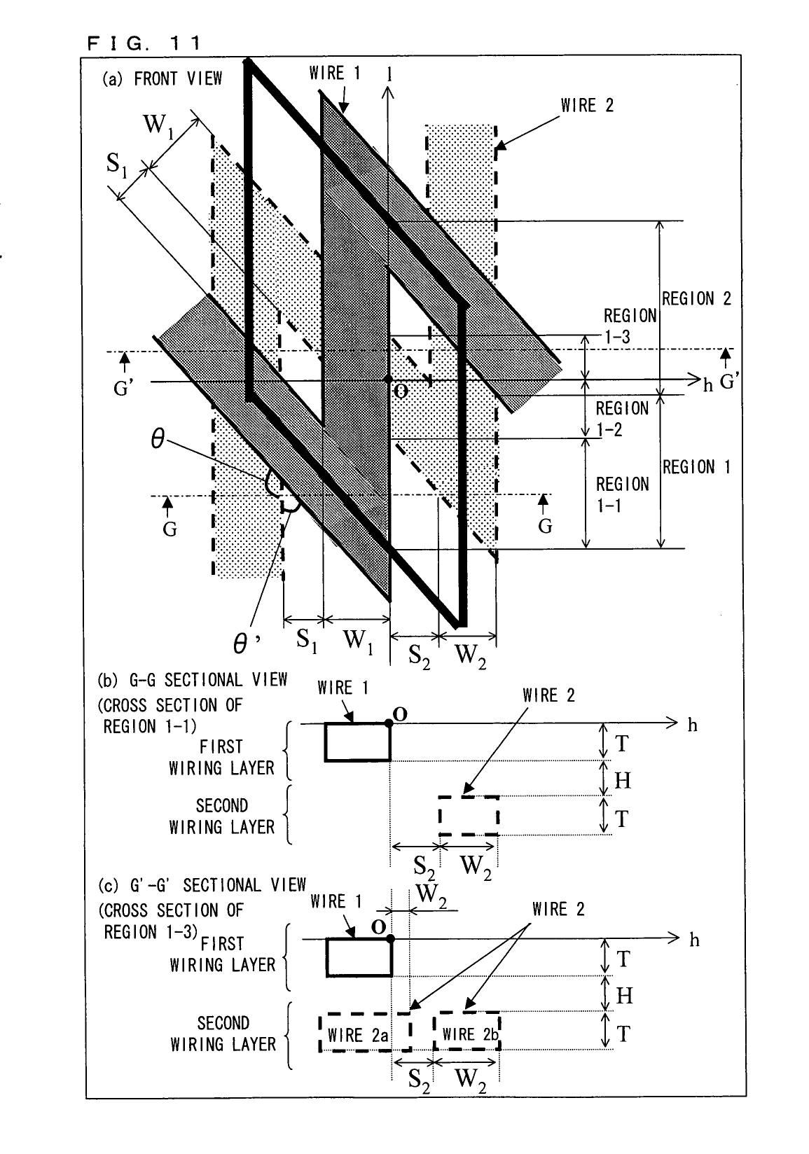

First, the case where the intersecting angle θ is a cute will be described. FIG. 10 is a diagram for calculating the fringe capacitance C_{fringe} per unit cell in the case where the intersecting angle θ is acute. FIG. 10(a) is a front view in which only one wire in the first wiring layer (hereinafter, referred to as a wire 1) and only one wire in the second wiring layer (hereinafter, referred to as a wire 2), which wires are shown as the wires of the unit cell in FIGS. 9 (a), are shown in order to facilitate understanding. As shown in FIG. 10(a), an l axis and an h axis which intersect with each other with a point O being an origin will be defined. The l axis and the h axis are located in the first wiring layer, and the l axis comes along a side face of the wire 1. Note that FIG. 10 (b) is a sectional view along a line F-F shown in FIG. 10(a).

Hereinunder, as shown in FIG. 10(a), a fringe capacitance per unit length with respect to each of five regions (regions 1 to 5) along the l axis is each calculated. The regions 1 to 5 can be expressed by a formula 4.

$$\begin{matrix}( region 1 ) & - \frac{{W}_{1} + {S}_{1}}{sin θ} \leq l < - \frac{{W}_{1} + 2 {S}_{1}}{2 sin θ} \\ ( region 2 ) & - \frac{{W}_{1} + 2 {S}_{1}}{2 sin θ} \leq l < - \frac{{W}_{1}}{2 sin θ} - \frac{{S}_{1}}{tan θ} \\ ( region 3 ) & - \frac{{W}_{1}}{2 sin θ} - \frac{{S}_{1}}{tan θ} \leq l < - \frac{{W}_{1}}{2 sin θ} \\ ( region 4 ) & - \frac{{W}_{1}}{2 sin θ} \leq l < \frac{{W}_{1}}{2 sin θ} \\ ( region 5 ) & \frac{{W}_{1}}{2 sin θ} \leq l < \frac{{W}_{1} + {S}_{1}}{sin θ}\end{matrix} \qquad [ Formula 4 ]$$

By obtaining the fringe capacitances dC/dl between an incremental division dl in the side face of the wire 1 in the h-axis direction and an upper face of the wire 2 with respect to the regions 1 to 5 and multiplying by 8 a sum of the fringe capacitances with respect to the regions 1 to 5, the fringe capacitance C_{fringe} per unit cell is calculated as shown in a formula 5.

$${C}_{fringe} = 8 {\int }_{- \frac{{W}_{1} + {S}_{1}}{sin θ}}^{\frac{{W}_{1} + {S}_{1}}{sin θ}} \frac{ⅆ C}{ⅆ l} ⅆ l \qquad [ Formula 5 ]$$

First, a fringe capacitance dC/dl between an incremental division dl in the side face of the wire 1 in the h-axis direction and the upper face of the wire 2 is calculated with respect to each of the regions 1 and 5. It can be considered that in the region 1, the wire 1 itself is connected to the side face (cross section) along the l axis of the wire 1. In the region 5, there is not the wire 2 on the h-axis direction side of the wire 1 (see FIG. 10(a)). Therefore, the fringe capacitance dC/dl between the incremental division dl in the side face of the wire 1 in the h-axis direction and the upper face of the wire 2 with respect to each of the regions 1 and 5 is calculated by using a formula 6.

$$\frac{ⅆ C}{ⅆ l} = 0 \qquad [ Formula 6 ]$$

However, a fringe capacitance between the side face of the wire 1 in the h-axis direction and the upper face of the wire, except the wire 2, in the second wiring layer is sufficiently small and is supposed to be negligible.

Next, a fringe capacitance dC/dl between an incremental division dl in the side face of the wire 1 in the h-axis direction and the upper face of the wire 2 with respect to the region 2 is calculated. Here, as shown in FIGS. 10 (a) and (b), it is supposed that in the sectional view along the line F-F which is away from the point O by an arbitrary distance, a width of the cross section of the wire 2 is W₂ and a space resulting between the wire 1 and the wire 2 in the h-axis direction is S₂. In this case, as understood from FIG. 10 (a), with respect to the region 2, a formula 7 is satisfied.
S₂=S₁, W₂=W₁ [Formula 7]
And the fringe capacitance dC/dl between the incremental division dl in the side face of the wire 1 in the h-axis direction and the upper face of the wire 2 with respect to the region 2 is calculated by using a formula 8.

$$In a case of {T}^{2} + 2 HT > {W}_{2}^{2} + 2 {S}_{2} {W}_{2} \\ \frac{ⅆ C}{ⅆ l} = \frac{{ɛ}_{r} {ɛ}_{0}}{π / 2} ln [ \frac{H + η T + \sqrt{{S}_{2}^{2} + {( η T )}^{2} + 2 H η T}}{{S}_{2} + H} ] \\ ∵ η = exp ( \frac{{W}_{2} + {S}_{2} - \sqrt{{S}_{2}^{2} + {T}^{2} + 2 HT}}{3.7 {W}_{2}} ) \\ In a case of {T}^{2} + 2 HT \leq {W}_{2}^{2} + 2 {S}_{2} {W}_{2} \\ \frac{ⅆ C}{ⅆ l} = \frac{{ɛ}_{r} {ɛ}_{0}}{π / 2} \cdot ln [ \frac{{S}_{2} + η {W}_{2} + \sqrt{{H}^{2} + {( η {W}_{2} )}^{2} + 2 {S}_{2} η {W}_{2}}}{{S}_{2} + H} ] \\ ∵ η = exp ( \frac{T + H - \sqrt{{H}^{2} + {W}_{2}^{2} + 2 {S}_{2} {W}_{2}}}{3.7 T} ) \qquad [ Formula 8 ]$$

Next, a fringe capacitance dC/dl between an incremental division dl in the side face of the wire 1 in the h-axis direction and an upper face of the wire 2 with respect to the region 3 is calculated. With respect to the region 3, S₂ is expressed by a

$${S}_{2} = - \frac{{W}_{1}}{2 cos θ} - l tan θ \qquad [ Formula 9 ]$$

With respect to the region 3, W₂ is expressed by a formula 10.
In a case of W₁/cos θ>W₁+S₁−S₂ W₂=W₁+X₁−S₂
In a case of W₁/cos θ≦W₁+S₁−S₂ W₂=W₁/cos θ [Formula 10]
And the fringe capacitance dC/dl between the incremental division dl in the side face of the wire 1 in the h-axis direction and the upper face of the wire 2 with respect to the region 3 is calculated by using the formula 8.

Next, a fringe capacitance dC/dl between an incremental division dl in a side face of the wire 1 in the h-axis direction and an upper face of the wire 2 with respect to the region 4 is calculated. With respect to the region 4, as understood from FIG. 10 (a), S₂=0 is satisfied. With respect to the region 4, W₂ is expressed by a formula 11.

$$In a case of \frac{{W}_{1}}{2 cos θ} - l tan θ > {W}_{1} + {S}_{1} \\ {W}_{2} = {W}_{1} + {S}_{1} \\ In a case of \frac{{W}_{1}}{2 cos θ} - l tan θ \leq {W}_{1} + {S}_{1} \\ {W}_{2} = \frac{{W}_{1}}{2 cos θ} - l tan θ \qquad [ Formula 11 ]$$

The fringe capacitance dC/dl between the incremental division dl in the side face of the wire 1 in the h-axis direction and the upper face of the wire 2 with respect to the region 4 is calculated by using a formula 12 in which S₂=0 is assigned into the formula 8.

$$In a case of {T}^{2} + 2 HT > {W}_{2}^{2} \\ \frac{ⅆ C}{ⅆ l} = \frac{{ɛ}_{r} {ɛ}_{0}}{π / 2} ln [ \frac{H + η T + \sqrt{{( η T )}^{2} + 2 H η T}}{H} ] \\ ∵ η = exp ( \frac{{W}_{2} - \sqrt{{T}^{2} + 2 HT}}{3.7 {W}_{2}} ) \\ In a case of {T}^{2} + 2 HT \leq {W}_{2}^{2} \\ \frac{ⅆ C}{ⅆ l} = \frac{{ɛ}_{r} {ɛ}_{0}}{π / 2} ln [ \frac{η {W}_{2} + \sqrt{{H}^{2} + {( η {W}_{2} )}^{2}}}{H} ] \\ ∵ η = exp ( \frac{T + H - \sqrt{{H}^{2} + {W}_{2}^{2}}}{3.7 T} ) \qquad [ Formula 12 ]$$

Through performing the calculations with the formula 5 by using each of the fringe capacitances dC/dl with respect to each of the regions 1 to 5 as calculated above, the fringe capacitance C_{fringe} per unit cell in the case where the intersecting angle θ is acute can be calculated.

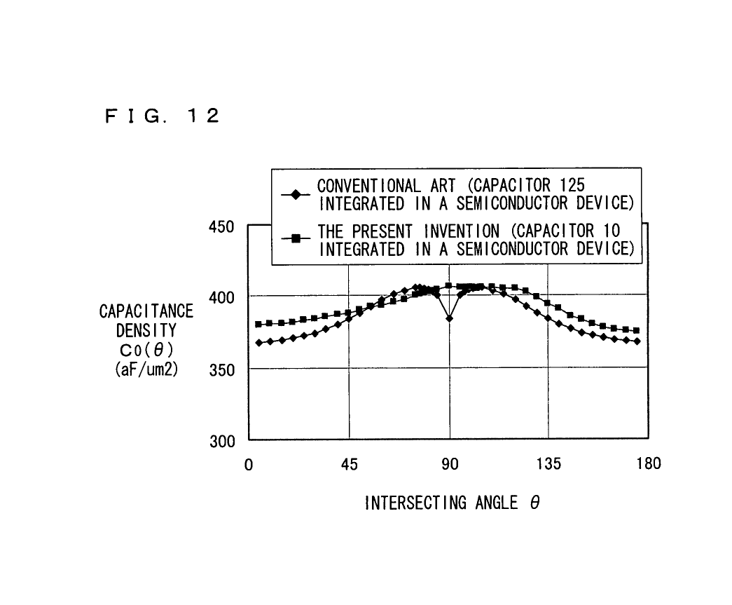

Next, the case where the intersecting angle θ is obtuse will be described. FIG. 11 is a diagram for calculating a fringe capacitance C_{fringe} per unit cell in the case where the intersecting angle θ is obtuse. FIG. 11(a) is a front view in which only one wire in the first wiring layer (hereinafter, referred to as a wire 1) and only one wire in the second wiring layer (hereinafter, referred to as a wire 2), which wires are shown as the wires of the unit cell in FIG. 9 (a), are shown in order to facilitate understanding. As shown in FIG. 11(a), an l axis and an h axis which intersect with each other with a point O being an origin will be defined. The l axis and the h axis are located in the first wiring layer, and the l axis comes along a side face of the wire 1. Note that FIG. 11 (b) is a sectional view along a line G-G shown in FIG. 11(a). FIG. 11 (c) is a sectional view along a line G′-G′ shown in FIG. 11(a).

Hereinunder, as shown in FIG. 11(a), a fringe capacitance per unit length with respect to each of two regions (regions 1 and 2) along the l axis is each calculated. Here, it is supposed that θ′=180°−θ is satisfied. The regions 1 and 2 can be expressed by a formula 13.

$$\begin{matrix}[ Formula 13 ] & \\ - \frac{{W}_{1}}{2 sin {θ}^{′}} - \frac{{W}_{1} + {S}_{1}}{tan {θ}^{′}} \leq l < \frac{2 {S}_{1} + {W}_{1}}{2 sin {θ}^{′}} - \frac{{S}_{1} + {W}_{1}}{tan {θ}^{′} } & ( region 1 ) \\ \frac{2 {S}_{1} + {W}_{1}}{2 sin {θ}^{′}} - \frac{{S}_{1} + {W}_{1}}{tan {θ}^{′} } \leq l < \frac{{W}_{1}}{2 sin {θ}^{′}} & ( region 2 )\end{matrix}$$

By obtaining the fringe capacitances dC/dl between an incremental division dl in the side face of the wire 1 along the l axis and an upper face of the wire 2 with respect to the regions 1 and 2 and multiplying the fringe capacitances by 8, the fringe capacitance C_{fringe} per unit cell is calculated as shown in a formula 14.

$${C}_{fringe} = 8 {\int }_{- \frac{{W}_{1}}{2 sin {θ}^{′}} - \frac{{W}_{1} + {S}_{1}}{tan {θ}^{′}}}^{\frac{{W}_{1}}{2 sin {θ}^{′}}} \frac{ⅆ C}{ⅆ l} ⅆ l \qquad [ Formula 14 ]$$

First, with respect to the region 2, a fringe capacitance between the incremental division dl in the side face of the wire 1 along the l axis and the upper face of the wire 2 will be calculated. With respect to the region 2, there is the wire 1 itself in the h-axis direction from the side face of the wire 1 along the l axis. Because of this, an electric flux line extending from the side face of the wire 1 along the l axis is blocked. As a result, the fringe capacitance between the incremental division dl in the side face of the wire 1 along the l axis and the upper face of the wire 2 with respect to the region 2 is calculated by using a formula 15.

$$\frac{ⅆ C}{ⅆ l} = 0 \qquad [ Formula 15 ]$$

Next, with respect to the region 1, a fringe capacitance between an incremental division dl in the side face of the wire 1 along the l axis and an upper face of the wire 2 will be calculated. Here, the region 1 is divided into three regions (regions 1-1 to 1-3) as shown in FIG. 11(a). The regions 1-1 to 1-3 can be expressed by a formula 16.

$$\begin{matrix}[ Formula 16 ] & \\ - \frac{{W}_{1}}{2 sin {θ}^{′}} - \frac{{W}_{1} + {S}_{1}}{tan {θ}^{′}} \leq l < - \frac{{W}_{1}}{2 sin {θ}^{′}} & ( region 1 - 1 ) \\ - \frac{{W}_{1}}{2 sin {θ}^{′}} \leq l < \frac{{W}_{1}}{2 sin {θ}^{′}} - \frac{{S}_{1}}{tan {θ}^{′}} & ( region 1 - 2 ) \\ \frac{{W}_{1}}{2 sin {θ}^{′}} - \frac{{S}_{1}}{tan {θ}^{′}} \leq l < \frac{2 {S}_{1} + {W}_{1}}{2 sin {θ}^{′}} - \frac{{S}_{1} + {W}_{1}}{tan {θ}^{′}} & ( region 1 - 3 )\end{matrix}$$

However, there may be a case where the regions 1-2 and 1-3 are not present in the region 1, depending on a magnitude of θ′. In a positional relationship (magnitude of θ′) shown in FIG. 11(a), the region 1-3 and a part of the region 1-2 are not present in the region 1. However, in order to facilitate understanding, the regions 1-2 and 1-3 are shown in FIG. 11(a), which are supposed as being present.

With respect to the region 1-1, a fringe capacitance between an incremental division dl in the side face of the wire 1 along the l axis and an upper face of the wire 2 will be calculated. Here, as shown in FIGS. 11 (a) and (b), it is supposed that in the sectional view along the line G-G, a width of the cross section of the wire 2 is W₂ and a space resulting between the wire 1 and the wire 2 in the h-axis direction is S₂. In this case, with respect to the region 1-1, a formula 17 is satisfied.

$${S}_{2} = - \frac{{W}_{1}}{2 cos θ} - l tan θ \\ {W}_{2} = {W}_{1} + {S}_{1} - {S}_{2} \qquad [ Formula 17 ]$$

With respect to the region 1-1, the fringe capacitance between the incremental division dl in the side face of the wire 1 along the l axis and the upper face of the wire 2 is calculated by using the formula 8 which is used for describing the region 2 in FIG. 10(a).

With respect to the region 1-2, a fringe capacitance between an incremental division dl in the side face of the wire 1 along the l axis and an upper face of the wire 2 will be calculated. With respect to the region 1-2, as understood from FIG. 11(a), a formula 18 is satisfied.
S₂=0, W₂=W₁+S₁ [Formula 18]
With respect to the region 1-2, the fringe capacitance between the incremental division dl in the side face of the wire 1 along the l axis and the upper face of the wire 2 is calculated by using the formula 12 which is used for describing the region 4 in FIG. 10(a).

With respect to the region 1-3, a fringe capacitance between an incremental division dl in the side face of the wire 1 along the l axis and an upper face of the wire 2 will be calculated. Here, as shown in FIGS. 11 (a) and (c), in the region 1-3, the wire 2 is divided into two pieces. In the region 1-3, the piece of the wire 2 which is close to the wire 1 is supposed to be a wire 2a and the piece of the wire 2 which is far from the wire 1 is supposed to be a wire 2b. Hereinunder, calculations for the wire 2a and the wire 2b are separately performed.

First, a fringe capacitance between an incremental division dl in the side face of the wire 1 along the l axis and an upper face of the wire 2a will be calculated. As shown in FIG. 11 (c), with regard to S₂ and W₂, a formula 19 is satisfied.

$${S}_{2} = 0 , {W}_{2} = \frac{{W}_{1}}{2 cos θ} - l tan θ \qquad [ Formula 19 ]$$

With respect to the region 1-3, the fringe capacitance between the incremental division dl in the side face of the wire 1 along the l axis and the upper face of the wire 2a is calculated by using the formula 12 which is used for describing the region 4 in FIG. 10 (a).

Next, a fringe capacitance between an incremental division dl in the side face of the wire 1 along the l axis and an upper face of the wire 2b will be calculated. As shown in FIG. 11 (c), with regard to S₂ and W₂, a formula 20 is satisfied.
S₂=S₁, W₂=W₁ [Formula 20]
With respect to the region 1-3, the fringe capacitance between the incremental division dl in the side face of the wire 1 along the l axis and the upper face of the wire 2b is calculated by using the formula 8 which is used for describing the region 2 in FIG. 10 (a).

The fringe capacitance between the incremental division dl in the side face of the wire 1 along the l axis and the upper face of the wire 2 with respect to the region 1-3 is a sum of the fringe capacitance with respect to the wire 2a and the fringe capacitance with respect to the wire 2b.

The fringe capacitance with respect to the region 1 is a sum of the fringe capacitances with respect to the regions 1-1 to 1-3.

Through performing the calculations with the formula 14 by using the above-calculated fringe capacitances dC/dl with respect to the regions 1 and 2, the fringe capacitance C_{fringe} per unit cell in the case where the intersecting angle θ is obtuse can be calculated.

As a result of the above-described calculations, a capacitance C₀ (θ) per unit are, which is generated in the capacitor 10 integrated in a semiconductor device, is calculated by using a formula 21.

$${C}_{0} ( θ ) = \frac{{C}_{side} + {C}_{plate} + {C}_{fringe}}{S} \qquad [ Formula 21 ]$$

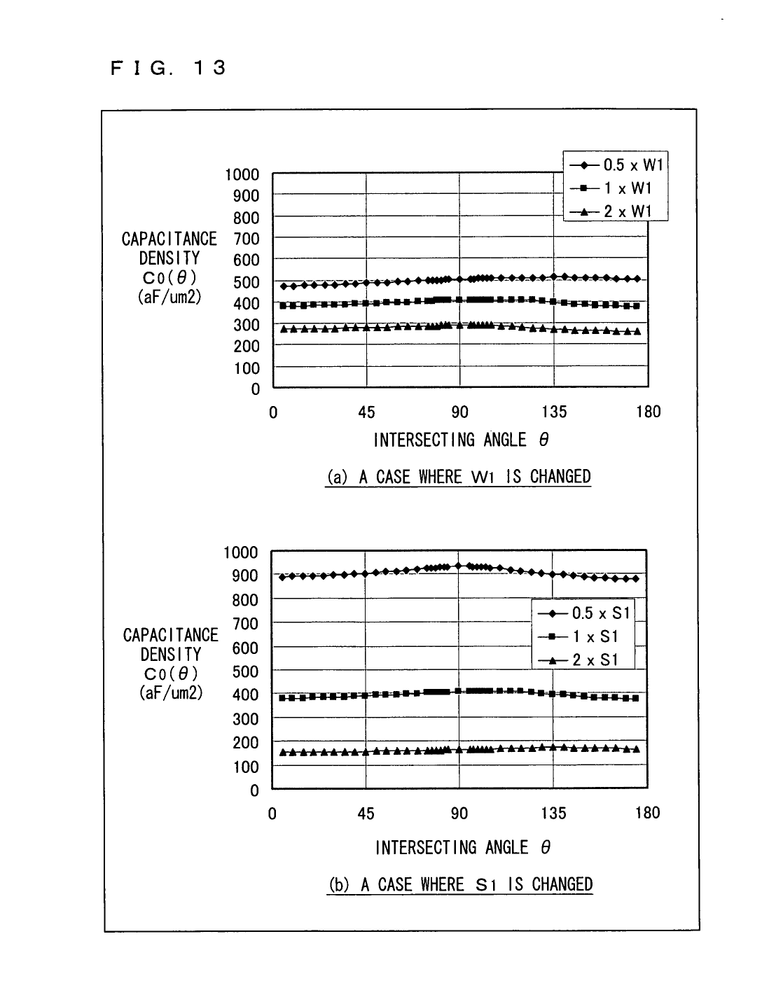

FIG. 12 is a diagram showing a calculation result of a capacitance C₀ (θ) per unit area, which is generated in the capacitor 10 integrated in a semiconductor device in a case where an intersecting angle θ is changed from 0° to 180°. Note that in FIG. 12, in order to make a comparison, a calculation result of a capacitance per unit area, which is generated in the conventional capacitor 125 integrated in a semiconductor device (see FIG. 24), is also shown. As shown in FIG. 12, a maximum value of the capacitance per unit area in the capacitor 10 integrated in a semiconductor device according to the present invention is substantially equal to that in the conventional capacitor 125 integrated in a semiconductor device. However, when the intersecting angle θ is 90° and is close to 90°, the capacitance per unit area in the capacitor 10 integrated in a semiconductor device according to the present invention is larger than that in the conventional capacitor 125 integrated in a semiconductor device.

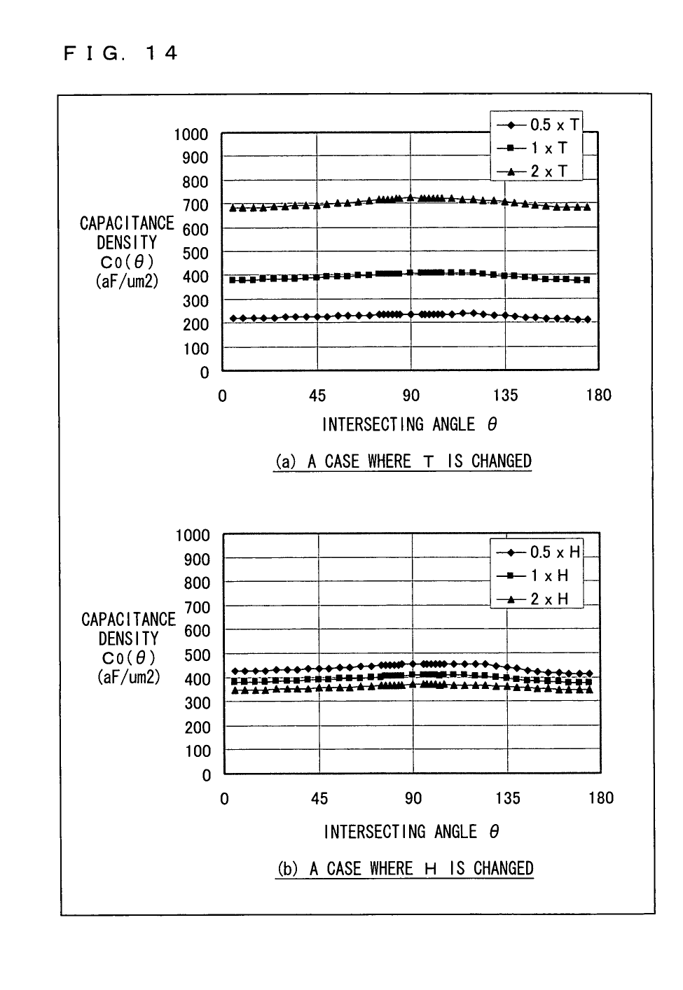

FIG. 13 is a diagram showing a calculation result of a capacitance C₀ (θ) per unit area, which is generated in the capacitor 10 integrated in a semiconductor device in a case where W₁ and S₁ are respectively changed. FIG. 14 is a diagram showing a calculation result of a capacitance C₀ (θ) per unit area, which is generated in the capacitor 10 integrated in a semiconductor device in a case where T and H are respectively changed. FIG. 13 (a) shows a capacitance C₀ (θ) per unit area in a case where W₁ is multiplied 0.5 times, 1 time, and 2 times. FIG. 13 (b) shows a capacitance C₀ (θ) per unit area in a case where S₁ is multiplied 0.5 times, 1 time, and 2 times. FIG. 14 (a) shows a capacitance C₀ (θ) per unit area in a case where T is multiplied 0.5 times, 1 time, and 2 times. FIG. 14 (b) shows a capacitance C₀ (θ) per unit area in a case where H is multiplied 0.5 times, 1 time, and 2 times. As shown in FIG. 13 and FIG. 14, even when W₁, S₁, T, and H are changed, a capacitance C₀ (θ) per unit area in the capacitor 10 integrated in a semiconductor device is a maximum or is a value extremely close to a maximum when the intersecting angle θ is 90°. Accordingly, even if W₁, S₁, T, and H are changed, a capacitance C₀ (θ) per unit area in the capacitor 10 integrated in a semiconductor device according to the present invention is larger than that in the conventional capacitor 125 integrated in a semiconductor device when the intersecting angle θ is 90° and is close to 90°.

Here, in general, designing and fabricating of a capacitor are easy when the intersecting angle θ is 90°. The capacitance per unit area in the conventional capacitor 125 integrated in a semiconductor device is greatly decreased when the intersecting angle θ which makes the fabrication or the like easy is 90°. On the other hand, as mentioned above, the capacitance C₀ (θ) per unit area in the capacitor 10 integrated in a semiconductor device is a maximum or is a value extremely close to a maximum when the intersecting angle θ which makes the fabrication or the like easy is 90°. As a result, it can be said that the capacitor 10 integrated in a semiconductor device according to the present invention is more practical than the conventional capacitor 125 integrated in a semiconductor device.

### Second Embodiment

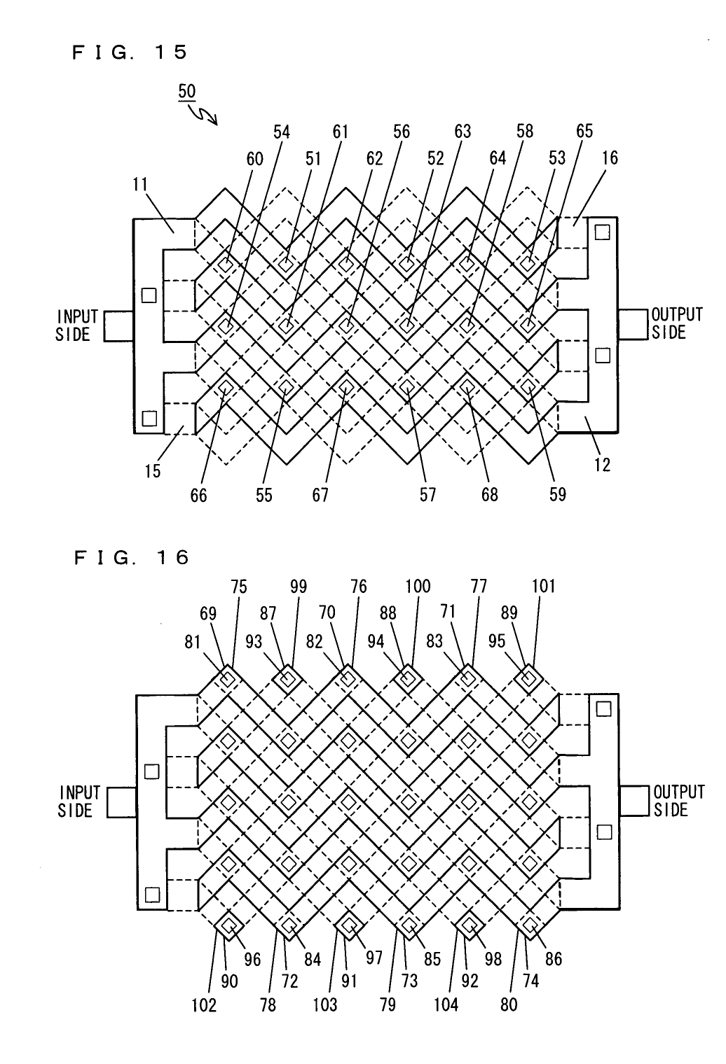

FIG. 15 is a diagram illustrating a configuration example of a capacitor 50 integrated in a semiconductor device according to a second embodiment. As shown in FIG. 15, the capacitor 50 integrated in a semiconductor device has a configuration in which in addition to the configuration of the capacitor 10 integrated in a semiconductor device according to the first embodiment, vias 51 to 59 which connect zigzag-shaped bending portions of a metal wire 11 on an input side, which is provided in a first wiring layer, with zigzag-shaped bending portions of a metal wire 15 on the input side, which is provided in a second wiring layer, are further included; and vias 60 to 68 which connect zigzag-shaped bending portions of a metal wire 12 on an output side, which is provided in the first wiring layer, with zigzag-shaped bending portions of a metal wire 16 on the output side, which is provided in a second wiring layer, are further included. The same reference numerals as those in the capacitor 10 integrated in a semiconductor device are used to denote the same components in the capacitor 50 integrated in a semiconductor device as those in the capacitor 10 integrated in a semiconductor device, and descriptions thereof will be omitted.

Owing to the above-mentioned configuration, the capacitor 50 integrated in a semiconductor device allows a capacitance per unit area to be further increased, as compared with the capacitor 10 integrated in a semiconductor device according to the first embodiment, because electric field coupling among the vias 51 to 68 which connect the metal wire in the first wiring layer with the metal wire in the second wiring layer is added.

In the above description, the vias are provided in the zigzag-shaped bending portions of the metal wires. However, the vias may connect portions at which zigzag-shaped wires of the metal wire 11 on the input side, which is provided in the first wiring layer and zigzag-shaped wires of the metal wire 15 on the input side, which is provided in the second wiring layer, overlap when viewed from a direction of lamination of the first wiring layer and the second wiring layer. Similarly, the vias may connect portions at which zigzag-shaped wires of the metal wire 12 on the output side, which is provided in the first wiring layer and zigzag-shaped wires of the metal wire 16 on the output side, which is provided in the second wiring layer, overlap when viewed from the direction of lamination of the first wiring layer and the second wiring layer.

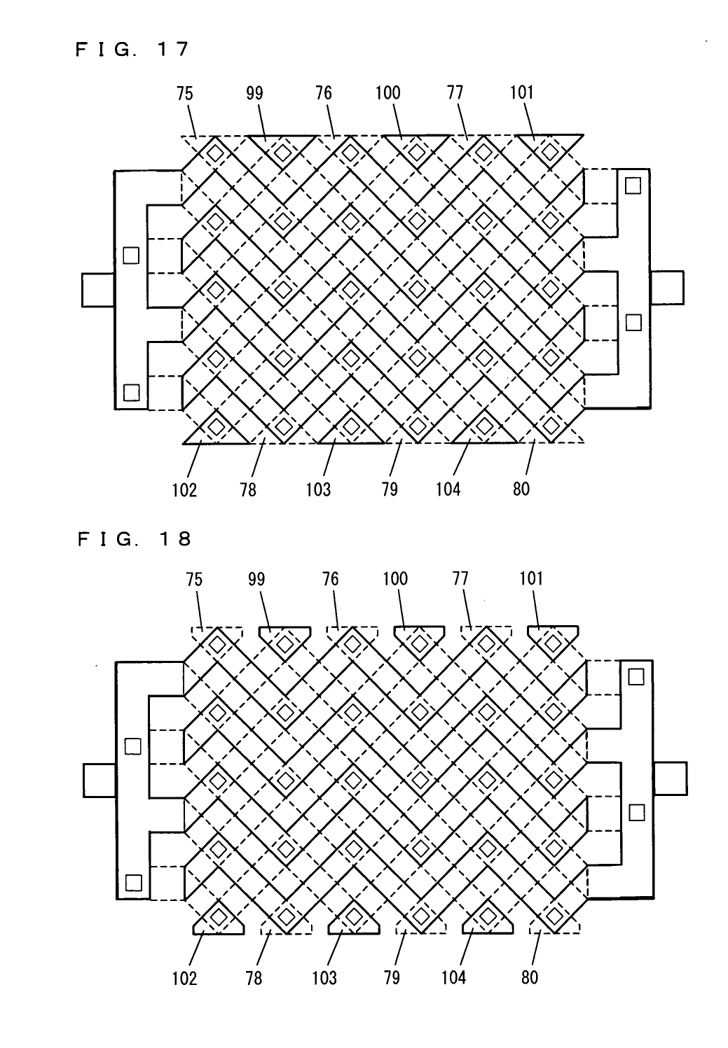

FIG. 16 is a diagram illustrating a configuration of a first modified example of the capacitor 50 integrated in a semiconductor device. Hereinunder, with reference to FIG. 16, the configuration of the first modified example will be described. The first modified example includes the following components in addition to the configuration of the capacitor 50 integrated in a semiconductor device (see FIG. 15).

The first modified example comprises vias 81 to 86 which are connected to peripheral bending portions 69 to 74, among square-shaped bending portions which zigzag-shaped wires arranged in the first wiring layer have, located in a periphery of regions where the zigzag-shaped wires are arranged. In addition, the first modified example comprises square-shaped floating wires 75 to 80, whose shapes are the same as those of the peripheral bending portions 69 to 74, respectively located on the second wiring layer and at positions where the peripheral bending portions 69 to 74 in the first wiring layer are projected to the second wiring layer by parallel light irradiated in a direction of lamination of the first wiring layer and the second wiring layer. The floating wires 75 to 80 are respectively connected to the vias 81 to 86. In other words, in the first modified example, each of the peripheral bending portions 69 to 74 in the first wiring layer is connected to each of the floating wires 75 to 80 through each of the vias 81 to 86. Similarly, the first modified example comprises vias 93 to 98 which are connected to peripheral bending portions 87 to 92, among square-shaped bending portions which zigzag-shaped wires arranged in the second wiring layer have, located in a periphery of regions where the zigzag-shaped wires are arranged. In addition, the first modified example comprises square-shaped floating wires 99 to 104, whose shapes are the same as those of the peripheral bending portions 87 to 92, respectively located on the first wiring layer and at positions where the peripheral bending portions 87 to 92 in the second wiring layer are projected to the first wiring layer by parallel light irradiated in the direction of lamination of the first wiring layer and the second wiring layer. The floating wires 99 to 104 are respectively connected to the vias 93 to 98. In other words, in the first modified example, each of the peripheral bending portions 87 to 92 in the second wiring layer is connected to each of the floating wires 99 to 104 through each of the vias 93 to 98.

Owing to such a configuration, electrolyzation coupling induced by the floating wires 75 to 80 and the zigzag-shaped wires of the metal wire 15 or the metal wire 16, which are adjacent to the floating wires 75 to 80, is added to electrolyzation coupling induced by the floating wires 99 to 104 and the zigzag-shaped wires of the metal wire 11 or the metal wire 12, which are adjacent to the floating wires 99 to 104. As a result, the first modified example of the capacitor 50 integrated in a semiconductor device allows a capacitance per unit area to be further increased, as compared with the capacitor 50 integrated in a semiconductor device (see FIG. 15).

FIG. 17 is a diagram illustrating a configuration of a second modified example of the capacitor 50 integrated in a semiconductor device. As shown in FIG. 17, in the second modified example, the shapes of the floating wires 75 to 80 and 99 to 104 are changed to be triangles, instead of the squares as in the first modified example shown in FIG. 16. The floating wires 75 to 80 are spaced with predetermined distances from the zigzag-shaped wires which are provided in the same wiring layer (second wiring layer) as that in which the floating wires 75 to 80 are provided and which zigzag-shaped wires are adjacent to the floating wires 75 to 80, the floating wires 75 to 80 having the triangle shapes whose areas are the largest. Similarly, the floating wires 99 to 104 are spaced with predetermined distances from the zigzag-shaped wires which are provided in the same wiring layer (first wiring layer) as that in which the floating wires 99 to 104 are provided and which zigzag-shaped wires are adjacent to the floating wires 99 to 104, the floating wires 99 to 104 having the triangle shapes whose areas are the largest.

Owing to such a configuration, areas of the floating wires 75 to 80 and 99 to 104 in the second modified example are larger than those of the floating wires 75 to 80 and 99 to 104 in the first modified example (see FIG. 16 and FIG. 17). Because of this, in the second modified example, electrolyzation coupling induced by the floating wires 75 to 80 and the zigzag-shaped wires of the metal wire 15 or the metal wire 16, which are adjacent to the floating wires 75 to 80, and electrolyzation coupling induced by the floating wires 99 to 104 and the zigzag-shaped wires of the metal wire 11 or the metal wire 12, which are adjacent to the floating wires 99 to 104 are larger than those in the first modified example. As a result, the second modified example of the capacitor 50 integrated in a semiconductor device allows a capacitance per unit area to be further increased, as compared with the fist modified example of the capacitor integrated in a semiconductor device (see FIG. 16).

In the above-described second modified example, as shown in FIG. 17, two interior angles of each of the triangles of the floating wires 75 to 80 and 99 to 104 are smaller than 90°. Here, there may be a case where such a shape constitutes a violation of rules in some semiconductor processes. FIG. 18 is a diagram illustrating a configuration of a third modified example of the capacitor 50 integrated in a semiconductor device. Consequently, for example, as shown in FIG. 18, by changing the shapes of the floating wires 75 to 80 and 99 to 104 to pentagons which are formed by cutting two angles, whose interior angles are smaller than 90°, of each of the triangles of the floating wires 75 to 80 and 99 to 104, the third modified example attains substantially the same effect as that obtained by the second modified example and can avoid the violation of rules in some semiconductor processes.

### Third Embodiment

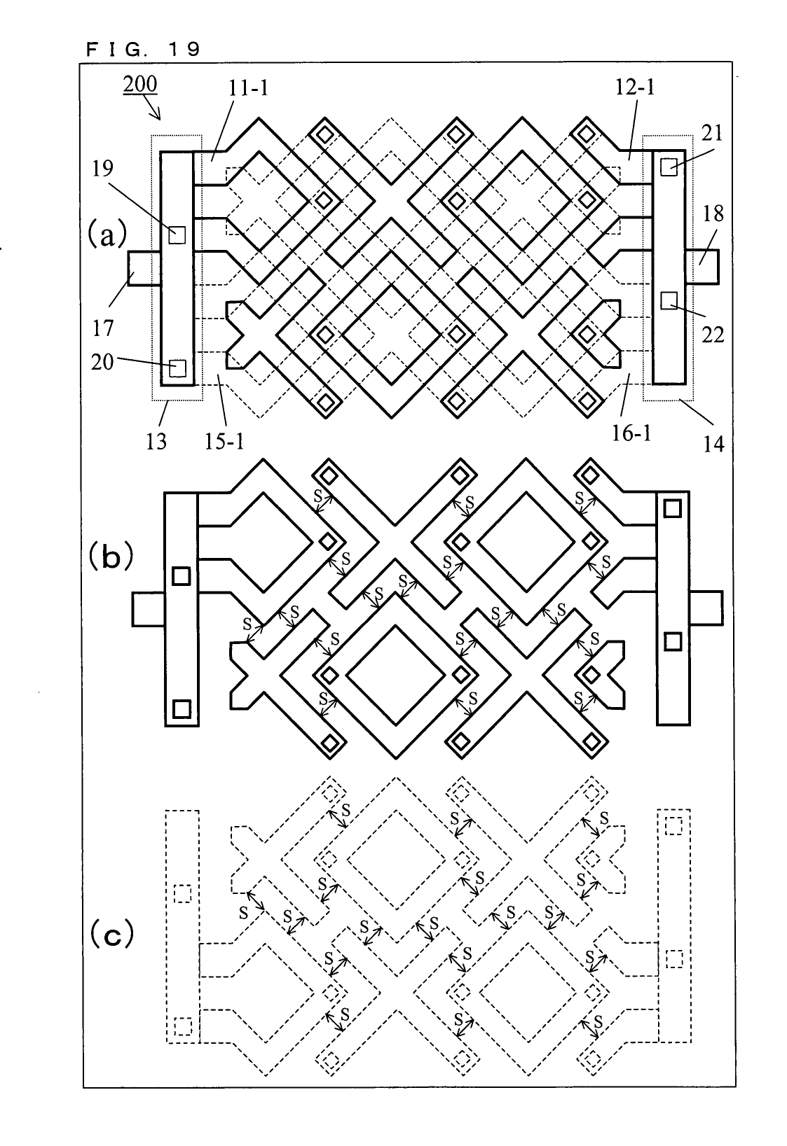

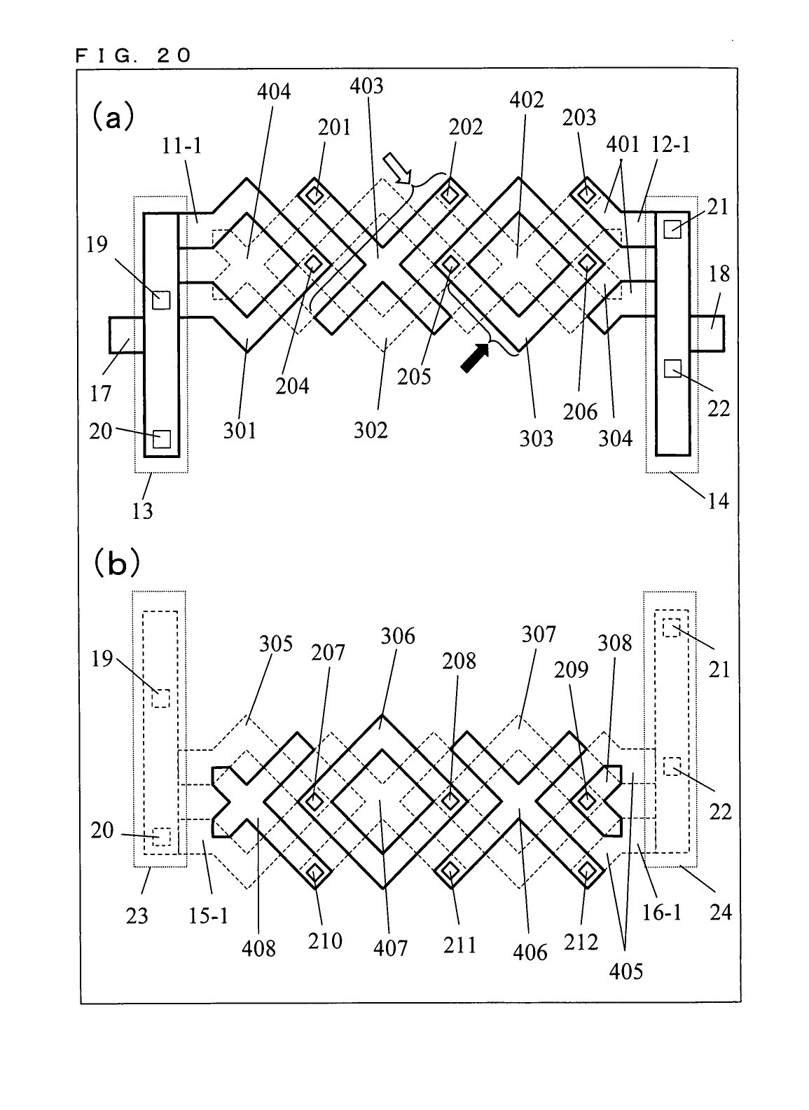

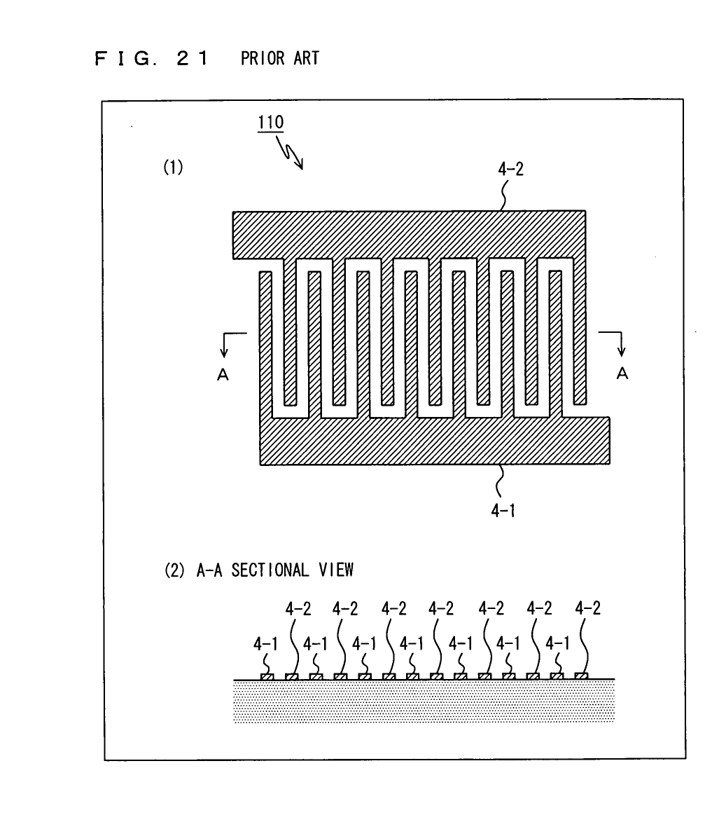

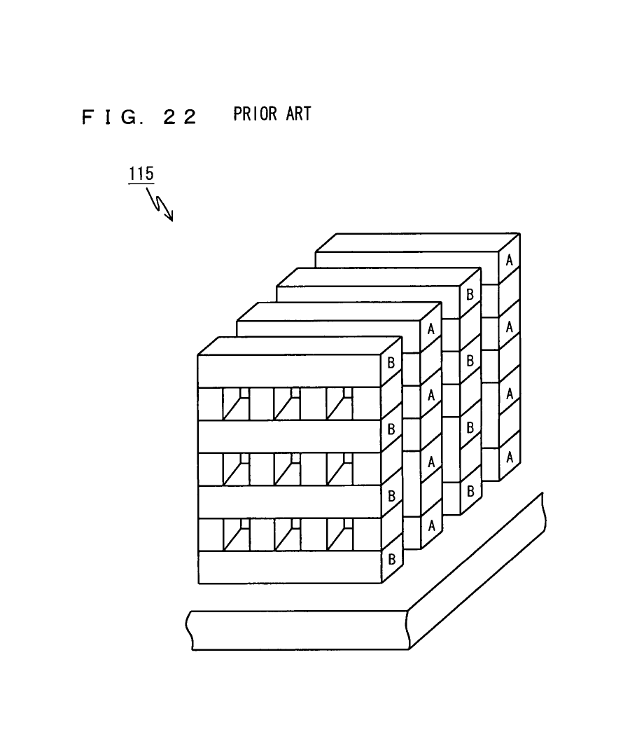

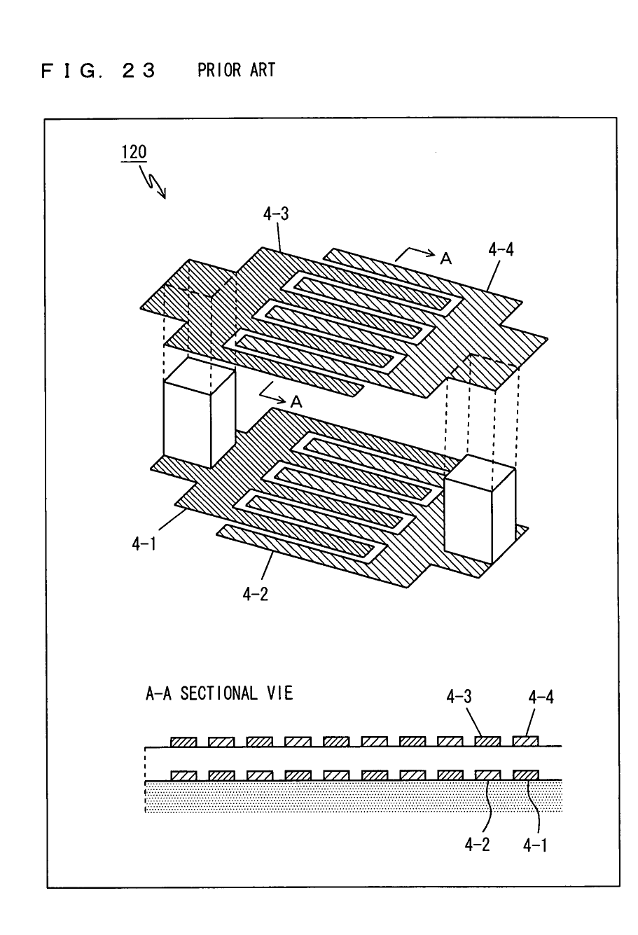

FIG. 19 is a diagram illustrating a configuration example of a capacitor 200 integrated in a semiconductor device according to a third embodiment of the present invention. As shown in FIG. 19 (a), the capacitor 200 integrated in a semiconductor device comprises a first wiring layer which is indicated by a solid line and a second wiring layer which is indicated by a dotted line. FIG. 19 (b) shows wires in the first wiring layer. FIG. 19 (c) shows wires in the second wiring layer. The capacitor 200 integrated in a semiconductor device has a configuration in which the metal wire 11, the metal wire 12, the metal wire 15, and the metal wire 16 in the capacitor 10 integrated in a semiconductor device according to the first embodiment (see FIG. 1) are replaced with a metal wire 11-1, a metal wire 12-1, a metal wire 15-1, and a metal wire 16-1, respectively. FIG. 20 is a diagram illustrating the metal wires 11-1, 12-1, 15-1, and 16-1. FIG. 20 (a) shows the metal wires 11-1, and 12-1. FIG. 20 (b) shows the metal wires 15-1, and 16-1. As shown in FIGS. 20 (a) and (b), the metal wires 11-1, 12-1, 15-1, and 16-1 have shapes which are formed by changing the shapes of the zigzag-shaped wires of the metal wires 11, 12, 15, and, 16. In FIGS. 20 (a) and (b), the wires located in the first wiring layer are indicated by a solid line and the wires located in the second wiring layer are indicated by a dotted line. The same reference numerals as those in the capacitor 10 integrated in a semiconductor device are used to denote the same components in the capacitor 200 integrated in a semiconductor device as those in the capacitor 10 integrated in a semiconductor device, and the same descriptions thereof will not be repeated.

Hereinunder, the shapes of the metal wires 11-1, 12-1, 15-1, and 16-1 will be described. As shown in FIG. 20 (a), the metal wire 11-1 includes quadrangular wires (hereinafter, referred to as quadrangle wires) 301, 302, 303, and 304. Each of the quadrangle wires can be considered as being a wire formed by regularly combining four linear-shaped wires, one unit of which (unit linear wire) is indicated by a black arrow in FIG. 20 (a). The quadrangle wire 301 is located in the first wiring layer and connected to a lead-out wire 13. The quadrangle wire 302 is located in the second wiring layer and connected through a via 204 to the quadrangle wire 301. The quadrangle wire 303 is located in the first wiring layer and connected through a via 205 to the quadrangle wire 302. The quadrangle wire 304 is located in the second wiring layer and connected through a via 206 to the quadrangle wire 303. Here, the quadrangle wires 301 and 304 are shown, due to limitations of space, such that the quadrangles thereof are cut.

The metal wire 12-1 includes wires 401, 402, 403, and 404 each formed by combining, in a crossed-manner, linear-shaped wires, one unit of which (unit linear wire) is indicated by a white arrow in FIG. 20 (a) (hereinafter, referred to as cross wires). The cross wire 401 is located in the first wiring layer and connected to a lead-out wire 14. The cross wire 402 is located in the second wiring layer and connected through a via 203 to the cross wire 401. The cross wire 403 is located in the first wiring layer and connected through a via 202 to the cross wire 402. The cross wire 404 is located in the second wiring layer and connected through a via 201 to the cross wire 403. Here, the cross wires 401 and 404 are shown, due to limitations of space, such that the cross shapes thereof are cut.

Next, as shown in FIG. 20(b), the metal wire 15-1 includes quadrangle wires 305, 306, 307, and 308. The quadrangle wire 305 is located in the second wiring layer and connected to a lead-out wire 23. The quadrangle wire 306 is located in the first wiring layer and connected through a via 207 to the quadrangle wire 305. The quadrangle wire 307 is located in the second wiring layer and connected through a via 208 to the quadrangle wire 306. The quadrangle wire 308 is located in the first wiring layer and connected through a via 209 to the quadrangle wire 307. Here, the quadrangle wires 305 and 308 are shown, due to limitations of space, such that the quadrangles thereof are cut.

The metal wire 16-1 includes cross wires 405, 406, 407, and 408. The cross wire 405 is located in the second wiring layer and connected to a lead-out wire 24. The cross wire 406 is located in the first wiring layer and connected though a via 212 to the cross wire 405. The cross wire 407 is located in the second wiring layer and connected through a via 211 to the cross wire 406. The cross wire 408 is located in the first wiring layer and connected through a via 210 to the cross wire 407. Here, the cross wires 405 and 408 are shown, due to limitations of space, such that the cross shapes thereof are cut.

Next, a positional relationship of the quadrangle wires of the metal wires 11-1 and 15-1 and the cross wires of the metal wires 12-1 and 16-1 will be described. The wires in the first wiring layer, shown in FIG. 19 (b), will be described. As shown in FIG. 19 (b), in the first wiring layer, the quadrangle wires and the cross wires are alternately arranged so as to be each spaced with a predetermined distance S. More specifically, each of the unit linear wires included in each of the quadrangle wires and each of the unit linear wires included in each of the cross wires are disposed so as to have a predetermined distance S between each other. Also in the second wiring layer shown in FIG. 19 (c), as in the first wiring layer shown in FIG. 19 (b), the quadrangle wires and the cross wires are alternately arranged so as to be each spaced with the predetermined distance. As shown in FIG. 19 (a), FIG. 20 (a), and FIG. 20 (b), the unit linear wires included in the quadrangle wires in the first wiring layer and the unit linear wires included in the cross wires in the second wiring layer three-dimensionally intersect when viewed from the direction of lamination of the wiring layers. Similarly, the unit linear wires included in the quadrangle wires in the second wiring layer and the unit linear wires included in the cross wires in the first wiring layer three-dimensionally intersect when viewed from the direction of lamination of the wiring layers.

Here, when a semiconductor is miniaturized, a gate of a field-effect transistor is easily damaged by static electricity. This is because when a length of a metal wire in an IC is long, the metal wire serves as an antenna and receives external static electricity. Therefore, there may be a case where a limit is set on the length of the metal wire in a same wiring layer.

The capacitor 200 integrated in a semiconductor device does not use the zigzag-shaped wires (see FIG. 1) whose wiring lengths are long and use the quadrangle wires and cross wires (see FIG. 19 and FIG. 20) whose wiring lengths are short. Owing to this, the capacitor 200 integrated in a semiconductor device according to the third embodiment allows a reduction in the lengths of the metal wires in a same wiring layer, as compared with the capacitor 10 integrated in a semiconductor device according to the first embodiment, which uses the zigzag-shaped wires. As a result, the capacitor 200 integrated in a semiconductor device according to the third embodiment attains the same effect as that obtained in the capacitor 10 integrated in a semiconductor device according to the first embodiment, and further, can avoid the damage by static electricity, which is caused when the metal wires serve as an antenna, satisfying a condition of the limit on the lengths of the metal wires.

Although it is preferable that the unit linear wires in the first wiring layer and the unit linear wires in the second wiring layer three-dimensionally intersect at 90° when viewed from the direction of lamination of the wiring layers, the present invention is not limited thereto. Although in the above description, the capacitor integrated in a semiconductor device, which comprises two layers of the first wiring layer and the second wiring layer is described, the capacitor integrated in a semiconductor device may comprise three or more wiring layers. In this case, a capacitance per unit area can be further increased. The numbers of the quadrangle wires and the cross wires are not limited to the numbers described above.

While the invention has been described in detail, the foregoing description is in all aspects illustrative and not restrictive. It is understood that numerous other modifications and variations can be devised without departing from the scope of the invention.

What is claimed is:

1. A capacitor integrated in a semiconductor device, which has a configuration in which N (N is an integer greater than or equal to 2) wiring layers are laminated, comprising:
a metal wire in a K layer, which is provided in a Kth wiring layer (K is any of 1 through N−1); and
a metal wire in a K+1 layer, which is provided in a K+1th layer,
wherein the metal wire in the K layer includes:
a first wire group including a plurality of first wires having predetermined shapes, which are formed by regularly combining first unit linear wires and a lead-out wires which connects the plurality of first wires having predetermined shapes to a first terminal; and
a second wire group including a plurality of second wires having predetermined shapes, which are formed by regularly combining second unit linear wires and a lead-out wire which connects the plurality of second wires having predetermined shapes to a second terminal,
wherein the metal wire in the K+1 layer includes:
a first wire group including a plurality of first wires having predetermined shapes, which are formed by regularly combining first unit linear wires and a lead-out wire which connects the plurality of first wires having predetermined shapes to the first terminal; and
a second wire group including a plurality of second wires having predetermined shapes, which are formed by regularly combining second unit linear wires and a lead-out wire which connects the plurality of second wires having predetermined shapes to the second terminal,
wherein the plurality of first wires having predetermined shapes and the plurality of second wires having predetermined shapes are alternately arranged in each of the wiring layers so as to be evenly spaced,
wherein the lead-out wire of the first wire group in the K layer and the lead-out wire of the first wire group in the K+1 layer are connected with each other so as to overlap with each other when viewed from a direction of lamination of the wiring layers,
wherein the lead-out wire of the second wire group in the K layer and the lead-out wire of the second wire group in the K+1 layer are connected with each other so as to overlap with each other when viewed from the direction of lamination of the wiring layers,
wherein the first unit linear wires in the K layer and the second unit linear wires in the K+1 layer three-dimensionally intersect when viewed from the direction of lamination of the wiring layers, respectively, and
wherein the first unit linear wires in the K+1 layer and the second unit linear wires in the K layer three-dimensionally intersect when viewed from the direction of lamination of the wiring layers, respectively.

2. The capacitor integrated in a semiconductor device according to claim 1,
wherein the first wires having predetermined shapes are zigzag-shaped wires formed by combining the first unit linear wires in a zigzag manner, and
wherein the second wires having predetermined shapes are zigzag-shaped wires formed by combining the second unit linear wires in a zigzag manner.

3. The capacitor integrated in a semiconductor device according to claim 2, wherein an angle at which the first unit linear wires in the K layer and the second unit linear wires in the K+1 layer intersect and at which the first unit linear wires in the K+1 layer and the second unit linear wires in the K layer intersect is each 90°.

4. The capacitor integrated in a semiconductor device according to claim 2,
wherein the metal wire in the K layer further includes zigzag-shaped floating wires, in a periphery of regions where the zigzag-shaped wires are arranged, which are evenly spaced in a manner adjacent to the zigzag-shaped wires on both edge portions of the arranged zigzag-shaped wires, and
wherein the metal wire in the K+1 layer further includes zigzag-shaped floating wires, in a periphery of regions where the zigzag-shaped wires are arranged, which are evenly spaced in a manner adjacent to the zigzag-shaped wires on both edge portions of the arranged zigzag-shaped wires.

5. The capacitor integrated in a semiconductor device according to claim 2, further comprising:
vias which respectively connect portions at which the zigzag-shaped wires in the K layer, which are connected to the first terminal, and the zigzag-shaped wires in the K+1 layer, which are connected to the first terminal, overlap with each other when viewed from the direction of lamination of the wiring layers; and
vias which respectively connect portions at which the zigzag-shaped wires in the K layer, which are connected to the second terminal, and the zigzag-shaped wires in the K+1 layer, which are connected to the second terminal, overlap with each other when viewed from the direction of lamination of the wiring layers.

6. The capacitor integrated in a semiconductor device according to claim 2, further comprising:
floating wires which are provided in the K+1 layer and correspond to peripheral bending portions when viewed from the direction of lamination of the wiring layers, among bending portions of the zigzag-shaped wires in the K layer, which are located in a periphery of regions where the zigzag-shaped wires are arranged;
floating wires which are provided in the K layer and correspond to peripheral bending portions when viewed from the direction of lamination of the wiring layers, among bending portions of the zigzag-shaped wires in the K+1 layer, which are located in a periphery of regions where the zigzag-shaped wires are arranged;
vias which connect the peripheral bending portions in the K layer and the floating wires in the K+1 layer, respectively; and
vias which connect the peripheral bending portions in the K+1 layer and the floating wires in the K layer, respectively.

7. The capacitor integrated in a semiconductor device according to claim 6, wherein shapes of the floating wires in the K+1 layer and of the floating wires in the K layer are square.

8. The capacitor integrated in a semiconductor device according to claim 6, wherein shapes of the floating wires in the K+1 layer and of the floating wires in the K layer are triangular.

9. The capacitor integrated in a semiconductor device according to claim 6, wherein shapes of the floating wires in the K+1 layer and of the floating wires in the K layer are pentagonal.

10. The capacitor integrated in a semiconductor device according to claim 1,
wherein the first wires having predetermined shapes are quadrangular wires formed by combining four pieces of the first unit linear wire in a quadrangular manner;
wherein the second wires having predetermined shapes are cross-shaped wires formed by combining two pieces of the second unit linear wire in a cross-shaped manner;
wherein the quadrangular wires in the K layer and the quadrangular wires in the K+1 layer are connected respectively through vias to the first terminal, and
wherein the cross-shaped wires in the K layer and the cross-shaped wires in the K+1 layer are connected respectively through vias to the second terminal.

11. The capacitor integrated in a semiconductor device according to claim 10, wherein an angle at which the first unit linear wires in the K layer and the second unit linear wires in the K+1 layer intersect and at which the first unit linear wires in the K+1 layer and the second unit linear wires in the K layer intersect is each 90°.
